(19) United States
(12) Patent Application Publication
(10) Pub. No.: US 2013/0200391 A1
(43) Pub. Date: Aug. 8, 2013

(54) GALLIUM NITRIDE BASED STRUCTURES WITH EMBEDDED VOIDS AND METHODS FOR THEIR FABRICATION

(71) Applicants: Salah M. Bedair, Raleigh, NC (US); Nadia A. El-Masry, Raleigh, NC (US); Pavel Frajtag, Raleigh, NC (US)

(72) Inventors: Salah M. Bedair, Raleigh, NC (US); Nadia A. El-Masry, Raleigh, NC (US); Pavel Frajtag, Raleigh, NC (US)

(73) Assignee: North Carolina State University, Raleigh, NC (US)

(21) Appl. No.: 13/876,132

(22) PCT Filed: Sep. 28, 2011
(86) PCT No.: PCT/US2011/053664

§ 371 Date: Mar. 26, 2013

Related U.S. Application Data
(60) Provisional application No. 61/387,324, filed on Sep. 28, 2010.

(51) Int. Cl. H01L 21/02; H01L 33/16; H01L 29/06

(52) U.S. Cl. CPC H01L 21/0259; H01L 29/0603; H01L 33/16
USPC 257/76; 438/494; 438/26

(57) ABSTRACT

A gallium nitride-based structure includes a substrate, a first layer of gallium nitride disposed on a growth surface of the substrate, and a second gallium nitride layer disposed on the first gallium nitride layer. The first layer includes a region in which a plurality of voids is dispersed. The second layer has a lower defect density than the gallium nitride of the interfacial region. The gallium nitride-based structure is fabricated by depositing GaN on the growth surface to form the first layer, forming a plurality of gallium nitride nanowires by removing gallium nitride from the first layer, and growing additional GaN from facets of the nanowires. Gallium nitride crystals growing from neighboring facets coalesce to form a continuous second layer, below which the voids are dispersed in the first layer. The voids serve as sinks or traps for crystallographic defects, and also as expansion joints that ameliorate thermal mismatch between the Ga.N and the underlying substrate. The voids also provide improved light transmission properties in optoelectronic applications.

### RELATED APPLICATIONS

This application claims the benefit of U.S. Provisional Patent Application Ser. No. 61/387,324, filed Sep. 28, 2010, titled “GALLIUM NITRIDE BASED STRUCTURES WITH EMBEDDED VOIDS AND METHODS FOR THEIR FABRICATION”, the content of which is incorporated by reference herein in its entirety.

### FEDERALLY SPONSORED SUPPORT

This invention was made with government support under Grant No. W911NF-09-1-0166 by the U.S. Army Research Office. The United States Government may have certain rights in the invention.

### TECHNICAL FIELD

The present invention relates generally to gallium nitride-based structures useful for a variety of optoelectronic microelectronic applications, and methods for fabricating such gallium nitride-based structures. The invention also relates to providing gallium nitride-based structures that exhibit uniformly reduced defect density.

### BACKGROUND

Group III-V compounds such as gallium nitride (GaN) and aluminum nitride (AlN) based compounds continue to be investigated for their use as direct bandgap semiconductors in optoelectronic devices such as light emitting diodes (LEDs) and laser diodes (LDs) and microelectronic devices such as RF devices and transistors. Group III nitrides have typically been grown heteroepitaxially in the [0001] direction (c-plane) on non-native substrates and thus are subject to the well-known disadvantages attending heteroepitaxy, i.e., mismatches in lattice constants and mismatches in thermal expansion coefficients. The selection of the substrate is thought to make the greatest impact on the performance of certain devices such as LEDs, and may be influenced by a variety of factors such as cost, diameter, availability, consistency of quality, thermal and structural properties, and resistivity. There is no single conventional substrate for which all of these parameters are optimal; a compromise must be made that strikes a balance between material quality and device performance of the deposited Group III nitride, device reliability, and manufacturability. High quality GaN was first achieved on sapphire and silicon carbide substrates and these substrates are currently the industry standards. While there has been a considerable effort to develop native substrates (e.g., homoepitaxy of GaN on GaN or AlN on AlN) or more closely lattice-matched substrates, nothing commercially viable has been produced thus far. After much intense effort, bulk native substrates remain prohibitively expensive and available only in limited sizes (about 1 in²). Also, for deep UV devices such as UV LEDs, AlN substrates exhibit significant UV absorption.

The performance of Group III nitrides in optoelectronic devices such as UV emitters is greatly influenced by the density of threading dislocations in these heteroepitaxially deposited films. For example, research efforts in the development of Group III nitride UV devices have resulted in devices operating over a wide range of UV wavelengths. See, e.g., Khan, Nature 2, 77. However, the relatively high dislocation densities in AlₓGa₁₋ₓN may be a limiting factor in the internal quantum efficiency (IQE) of these devices. Quantum efficiencies of deep UV LEDs are lower than 1%, suggesting the presence of non-radiative carrier recombination in AlₓGa₁₋ₓN with high values of x. Also, power devices and high-speed devices based on GaN are gaining considerable momentum. Defect reduction in these devices will lead to high breakdown voltage, reduced leakage current, better yield and reliability, low noise figures, and other improved characteristics. Various approaches have been taken for reducing defect density in GaN and AlGaN films, including lateral epitaxial overgrowth (LEO) or epitaxial lateral overgrowth (ELOG), lateral overgrowth in grooves and trenches, strained layer superlattices, pulsed atomic layer epitaxy (ALE), SiH₄+NH₃ treatment for partial in-situ surface etching, Si doping and others. See Sakai et al., J. Cryst. Growth, 221, 334-337 (2000); Pakula et al., J. Cryst. Growth, 267, 1-7 (2004); Tang et al., IEEE Transactions on Electronic Devices, 57, 1 (2010). Thus far, such approaches have met with limited success. While low densities of dislocations have been achieved via LEO (see Nam et al., Appl. Phys. Lett., 71, 2638-2640 (2009)), such an approach produces regions with both high and low dislocation density, i.e., non-uniform dislocation density. Moreover, LEO is problematic due to interaction of Al with the SiO₂ mask materials typically used in this technique. Also, both Si and O₂ can be sources of contamination in the high-temperature grown AlGaN layers. Alternatively, dislocations density may be reduced locally by utilizing re-growth of AlGaN on etched grooves/strip structures. The threading dislocations incline toward the center of the grooves, forming localized areas of low dislocation density in the range of 10⁷ cm⁻² above the sidewalls of the grooves. The rest of the AlGaN material, grown directly on c-plane surfaces, has a high dislocation density in the range of 10⁹ cm ⁻². See Detchprohm, Phy. Stat. Sol. 188 799; Imura, J. Crystal Growth 289 257. There is also severe roughness at the planes where the two fronts coalesce. Additionally, the use of strained AlGaN/AlN superlattices was found to be ineffective in reducing edge dislocations and found to have only partial success with screw and mixed dislocations in AlGaN. Also, the use of pulsed ALE to reduce strain and allow faster migration of Al species has been found not to result in dislocation reduction. See Sun, APL 87 211915. Other attempts to reduce defect density have included the use of AlN substrates, an epitaxial technique using AlN/AlGaN striped layers (Zhang APL 80, 3542), an intermediate buffer layer (Xi, J. Cryst. Growth 299 59) and others (Khan, Nature 2 77). However, dislocation density in the 10⁹ cm⁻² range was reported for these films. In general, approaches to achieve a low dislocation density in GaN templates over large area substrates have had limited success and areas with both low and high dislocations densities (about 10⁹ cm⁻²) still persist. Thus, it may be concluded that the current epitaxial growth of GaN and AlGaN templates with uniform low density of dislocations has not been reported.

Moreover, it is widely accepted that silicon has numerous advantages as a substrate choice for Group III nitride heteroepitaxy. It is an extremely mature substrate technology, where wafers 300 mm in diameter and larger are readily available from a multiplicity of vendors for a few tens of dollars per wafer. Due to the maturity of the silicon wafer industry, substrate quality is extremely high and wafer-to-wafer consistency is superb. No other electronic or optoelectronic substrate platform comes close to competing with silicon in this regard. The availability of very large-diameter, high-quality silicon substrates suggests that a GaN-on-silicon approach is one of the only platforms with an immediate roadmap to wafer sizes 150 mm in diameter and beyond. From a manufacturing standpoint, choosing silicon as the substrate would also leverage the capability to use existing high volume silicon process services and assembly houses (e.g., wafer thinning, via technology, dicing, etc.). Recently, several companies have been investigating growth of GaN on silicon substrates. For example, Nitronex has reported 0.8 μn thick, crack-free GaN on (111) silicon substrates with defect density in the 10⁹ cm⁻² range. Azzurro has reported the growth of thick GaN on crack-free (111), (100) and (110) silicon substrates, and has also fabricated blue and green LEDs on silicon substrates. The output of these LEDs is very low compared to those on SiC or sapphire substrates. The defect density in these GaN on silicon structures was not reported but is thought to be high. Unfortunately, the growth of GaN on silicon has posed many challenges due to the thermal and lattice mismatches between these materials.

Accordingly, there is an ongoing need for GaN-based structures and methods for their fabrication that reduce defect density in the GaN crystal to acceptable device-quality levels. There is also a need for providing low-defect density GaN and AlGaN in which the defect density is uniform. There is also a need for successfully fabricating low-defect density GaN and AlGaN on a wider range of substrates, particularly low-cost, high-quality substrates such as silicon.

### SUMMARY

To address the foregoing problems, in whole or in part, and/or other problems that may have been observed by persons skilled in the art, the present disclosure provides methods, processes, systems, apparatus, instruments, and/or devices, as described by way of example in implementations set forth below.

According to one implementation, a gallium nitride-based structure includes a substrate including a growth surface, a first layer of gallium nitride disposed on the growth surface, and a second gallium nitride layer disposed on the first gallium nitride layer. The first gallium nitride layer includes an interfacial region proximate to the growth surface and a plurality of voids dispersed in the interfacial region. The second gallium nitride layer has a defect density lower than a defect density of the gallium nitride of the interfacial region.

In some implementations, the second gallium nitride layer has a thickness of 2 μm or greater. In some implementations, the second gallium nitride layer has a thickness ranging from 2 to 8 μm.

According to another implementation, a method is provided for fabricating a gallium nitride-based structure. Gallium nitride is deposited on a growth surface of a substrate to form a first gallium nitride layer having a thickness in a growth direction. A plurality of gallium nitride nanowires is formed by removing gallium nitride from the first gallium nitride layer, such that the gallium nitride nanowires extend from the growth surface along the growth direction and include respective tip regions, and the tip regions include facets such as, for example, semipolar facets. Additional gallium nitride is deposited to grow gallium nitride crystals from the facets, wherein gallium nitride crystals growing from neighboring facets coalesce to form a continuous second gallium nitride layer, and a plurality of voids are dispersed throughout an interfacial region of the first gallium nitride layer between the growth surface and the second gallium nitride layer. Deposition of the additional gallium nitride continues until a desired thickness of the second gallium nitride layer is obtained.

In some implementations, the additional gallium nitride is deposited at a growth temperature ranging from 900 to 1050° C.

According to another implementation, a light emitting diode includes a plurality of gallium nitride nanowires of a first conductivity type (n-type or p-type), a plurality of indium gallium nitride/gallium nitride multi-quantum wells disposed on facets of the nanowires, and a continuous gallium nitride layer of a second conductivity type (p-type or n-type) disposed on the multi-quantum wells.

According to another implementation, a method is provided for fabricating a light emitting diode. A plurality of gallium nitride nanowires of a first conductivity type is formed. A plurality of indium gallium nitride/gallium nitride multi-quantum wells is deposited on facets of the nanowires. A continuous gallium nitride layer of a second conductivity type is deposited on the multi-quantum wells.

Other devices, apparatus, systems, methods, features and advantages of the invention will be or will become apparent to one with skill in the art upon examination of the following figures and detailed description. It is intended that all such additional systems, methods, features and advantages be included within this description, be within the scope of the invention, and be protected by the accompanying claims.

### BRIEF DESCRIPTION OF THE DRAWINGS

The invention can be better understood by referring to the following figures. The components in the figures are not necessarily to scale, emphasis instead being placed upon illustrating the principles of the invention. In the figures, like reference numerals designate corresponding parts throughout the different views.

FIGS. 1A-1D are schematic perspective views of a GaN-based structure or article at various stages of fabrication according to the present teachings.

FIGS. 2A-2C are schematic cross-sectional views of the GaN-based structure during various stages of fabrication similar to FIGS. 1A-1D, and additionally depicting the dislocation configuration of various regions after each stage.

FIGS. 3A and 3B are schematic cross-sectional views of a GaN-based structure illustrating the mechanism by which voids are formed during fabrication according to the present teachings.

FIG. 4 is a SEM cross-sectional view of a GaN film regrown from GaN nanowires by MOCVD according to the present teachings.

FIG. 5A is a TEM image of a continuous n-GaN film grown on a sapphire substrate by MOCVD.

FIG. 5B is a TEM image of an n-GaN layer overgrown on n-GaN nanowires according to the present teachings, in comparison to FIG. 5A.

FIG. 6A is a high-resolution SEM (HRSEM) image of GaN nanowires formed by mask-less ICP/RIE etching of GaN films grown on sapphire substrates according to the present teachings.

FIG. 6B is a high-resolution SEM (HRSEM) image of GaN nanowires after annealing followed by partial GaN overgrowth.

FIGS. 7A-7F are HRSEM images of a sample surface (plane view) showing different growth stages of GaN growing from nanowires according to the present teachings.

FIG. 8A is a schematic cross-sectional view of a GaN-based structure similar to FIG. 3B, illustrating the formation of V-shapes of nanowires of substantially the same height in the 2D projection (pyramidal cones in the 3D view) from different facets in two major crystallographic zone views of the GaN hexagonal system on (0001) sapphire substrate.

FIG. 8B is a schematic cross-sectional view of a GaN-based structure similar to FIG. 8B, illustrating growth from nanowires of different heights and forming a ½ V-shape in the 2D projection (a ½ pyramidal cone in the 3D view).

FIG. 8C is a legend pertaining to FIGS. 8A and 8B.

FIGS. 9A-9C are bright-field (BF) TEM images in m-plane view (m-zone) illustrating void formation, and fabrication of an LED from nanowires according to the present teachings and having the following configuration: (p-GaN)/(InGaN/GaN) MQWs/(n-GaN).

FIGS. 10A and 10B are another set of TEM images showing the formation of voids.

FIGS. 11A and 11B are sets of bright-field (BF) and dark-field (DF) TEM images of GaN films grown on GaN nanowires formed by etching a GaN film initially grown on a sapphire substrate according to the present teachings.

FIG. 12A is an AFM image of a GaN film overgrown on a c-plane GaN film grown on a sapphire substrate (without nanowires).

FIG. 12B is an AFM image of a GaN film grown by overgrowth on nanowires on a sapphire substrate in accordance with the present teachings, in comparison to FIG. 12A.

FIG. 13A shows a direct comparison of XRD rocking curve FWHM peaks on different (hk.1) crystallographic planes obtained from continuously grown GaN film and a GaN film with embedded voids.

FIG. 13B shows a comparative XRD analysis of a continuously grown GaN film and a GaN film with embedded voids, for calculating both the screw and edge components of dislocation density.

FIGS. 14A-14D are HRSEM images of a GaN film re-grown on nanowires formed from a GaN film initially grown on a silicon substrate according to the present teachings, showing the planarization effect.

FIGS. 15A and 15B are a pair of HRSEM images (two different magnifications) of a GaN film re-grown on nanowires formed from a GaN film initially grown on a silicon substrate according to the present teachings.

FIG. 16A is a TEM image showing different thicknesses of GaN film overgrowth on a {1-101} semi-polar plane and a {1-100} non-polar m-plane of GaN.

FIG. 16B is a graph plotting the normalized growth rate of GaN films on different semi-polar and non-polar planes (facets) according to polar c-plane growth.

FIG. 17A is set of plots of EL-emission spectrum from sidewall-based LED as a function of wavelength (λ) for various injection current densities.

FIG. 17B is a pair of plots of wavelength as a function of applied current for a sidewall-based LED and a c-plane based LED.

FIG. 17C is a set of plots showing the relationship between wavelength (λ) (nm), full width at half maxima (FWHM) (nm) and applied current (mA) or applied current density (mA/cm²).

FIG. 18A illustrates a direct comparison of photoluminescence (PL) (intensity in arbitrary units as a function of wavelength λ in nm) exhibited by a MQW structure on nanowires (a left half of the experimental sample) versus PL emission of a MQW structure on unetched c-plane GaN (a right half of the experimental sample) under the same growth conditions. Different wavelength emissions were obtained in those two cases.

FIG. 18B illustrates a direct comparison of electroluminescence (EL) emission (intensity in arbitrary units as a function of wavelength λ in nm) exhibited by an LED fabricated on nanowires (a right half of the experimental sample) versus EL emission of an LED fabricated on unetched c-plane GaN (a left half of the experimental sample). Both LED structures have been grown under the same growth conditions within one experimental sample. Different wavelength emissions were obtained in those two cases.

FIG. 19A depicts shear stress τ acting on a GaN film deposited on a silicon substrate.

FIG. 19B plots shear stress as a function on the dimension x depicted in FIG. 19A.

FIG. 19C is a schematic cross-sectional view of a GaN film on a silicon substrate, where the GaN film includes a network of voids generated as disclosed herein.

FIG. 20 is a schematic cross-sectional view of a GaN film on a silicon substrate in which expansion of the voids is depicted by arrows and contraction of the voids is depicted by other arrows.

FIGS. 21A-21C are high-resolution SEM (HRSEM) images of GaN nanowires, respectively having different contents of Al (AlₓGa₁₋ₓN where 0<x<1), specifically 0% Al, 20% Al and 30% Al, formed by mask-less ICP/RIE etching of GaN films grown on sapphire substrates according to the present teachings.

FIG. 22 illustrates photoluminescence (PL) data (intensity in arbitrary units as a function of wavelength in nm) obtained from GaN film as conventionally grown before ICP/RIE etching, from GaN nanowires after etching and from GaN film after total nanowires' overgrowth.

FIGS. 23A and 23B are HRSEM images of the respective surfaces of the two GaN samples (as grown, and after re-growth with embedded voids) of FIGS. 12A and 12B, which were utilized to conduct etch pit counts.

### DETAILED DESCRIPTION

For purposes of the present disclosure, it will be understood that when a layer (or film, region, substrate, component, device, or the like) is referred to as being “on” or “over” another layer, that layer may be directly or actually on (or over) the other layer or, alternatively, intervening layers (e.g., buffer layers, transition layers, interlayers, sacrificial layers, etch-stop layers, masks, electrodes, interconnects, contacts, or the like) may also be present. A layer that is “directly on” another layer means that no intervening layer is present, unless otherwise indicated. It will also be understood that when a layer is referred to as being “on” (or “over”) another layer, that layer may cover the entire surface of the other layer or only a portion of the other layer. It will be further understood that terms such as “formed on” or “disposed on” are not intended to introduce any limitations relating to particular methods of material transport, deposition, fabrication, surface treatment, or physical, chemical, or ionic bonding or interaction.

As used herein, the terms “Group III nitride,” “gallium nitride,” “GaN,” “AlGaN,” “AlGaInN” and (In, Al, Ga)N are each intended to encompass binary, ternary, and quaternary gallium nitride-based compounds such as, for example, gallium nitride, indium nitride, aluminum nitride, aluminum gallium nitride, indium gallium nitride, indium aluminum nitride, and aluminum indium gallium nitride, and alloys, mixtures, or combinations of the foregoing, with or without added dopants, impurities or trace components, as well as all possible crystalline structures and morphologies, and any derivatives or modified compositions of the foregoing. Unless otherwise indicated, no limitation is placed on the stoichiometries of these compounds. Thus, for convenience and by way of shorthand notation, any of the terms “Group III nitride,” “gallium nitride,” “GaN,” “AlGaN,” “AlGaInN” and (In, Al, Ga)N encompasses the class of materials characterized by the formula AlₓGa_{y}In_{z}N where x+y+z=1, 0≦x≦1, 0≦y≦1, 0≦z≦1.

As used herein, the term “nanowire” refers to a GaN crystal that has a characteristic dimension (e.g., diameter) in the nanometer (nm) range (e.g., 0.1 to 999.9 nm), and which is elongated relative to the characteristic dimension. The “characteristic dimension” will depend on the shape of the cross-section of the nanowire. Typically, the nanowire has a round (e.g., circular or approximately circular) cross-section in which case the characteristic dimension may be considered as a diameter. In other examples, the nanowire may have a more rectilinear cross-section in which case the characteristic dimension may be considered as a width. The nanowire is “elongated” in the sense that its other primary dimension (i.e., length or height) is appreciably greater than its characteristic dimension and typically is in the micrometer (μm) range, such as a fraction of a micrometer or a few (e.g., 1 to 3) micrometers (or microns). Accordingly, the nanowire may be characterized as having a high aspect ratio (e.g., length:diameter).

As used herein, the term “defect density” refers to the density of defects over a planar area, which may be a surface or a plane through a layer of material. The defects are typically crystallographic dislocations. Unless otherwise specified, the dislocations may include threading, edge, screw, and mixed dislocations. Defect density may be expressed interchangeably as defects (or dislocations) per cm², defects (or dislocations)/cm², or defects (or dislocations) cm⁻².

The present disclosure adopts a convention for numerical values according to the following example. The number 10⁸ encompasses the range between (and including) 1×10⁸ to 9×10⁸. Numbers in this range are considered to be values on the order of 10⁸. A number less than 1×10⁸ is considered to be a value on the order of 10⁷. A number greater than 9×10⁸ is considered to be a value on the order of 10⁹.

The present disclosure describes GaN-based structures and their fabrication. The approach taken to fabricating a GaN-based structure entails the creation of micron-sized voids that offer free surfaces for terminating (sinking) all kinds of dislocations, and re-growing GaN material above the voids to form a low-defect GaN layer. The voids have been found to be effective in reducing not only screw and mixed dislocations but also edge dislocations. Moreover, the reduced defect density has been found to be uniform throughout the area of the re-grown GaN material. The voids have also been found to be effective for compensating for thermal mismatch, whereby high-quality, low-defect GaN material may be grown from a wide range of substrates including, for example, silicon. The voids also form scattering regions, or wave guided regions, which improves light extraction efficiency in optoelectronic applications.

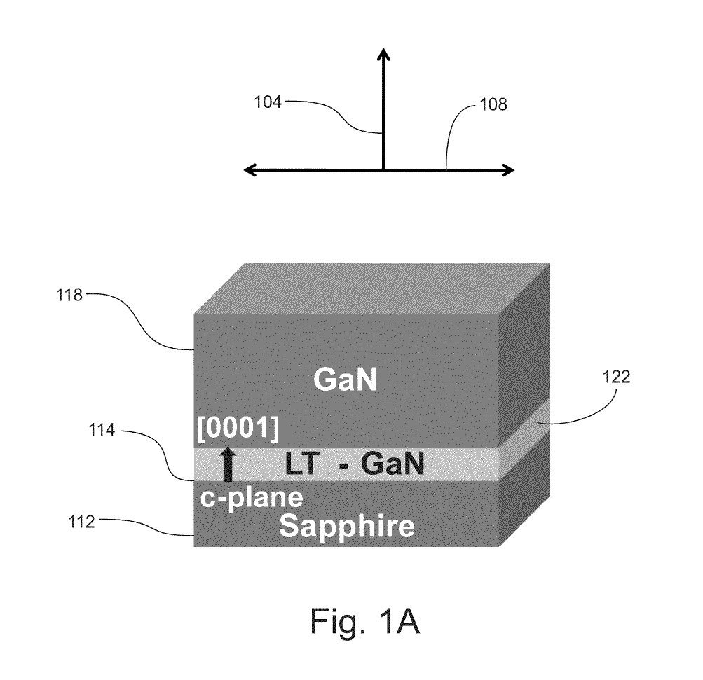

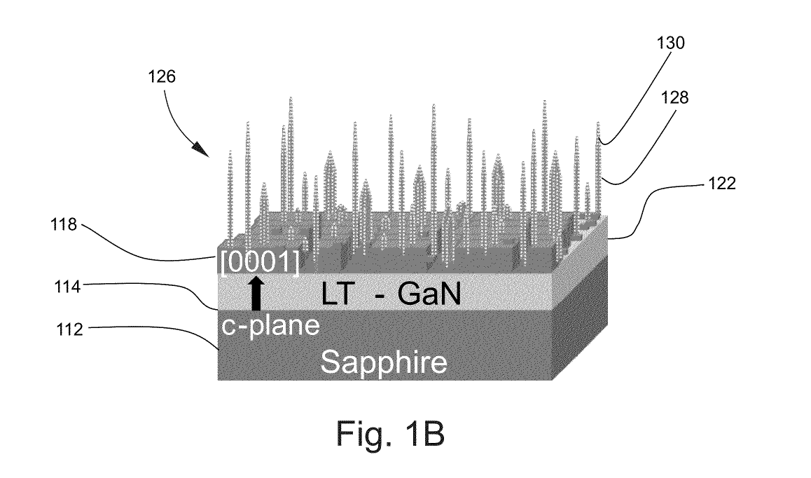

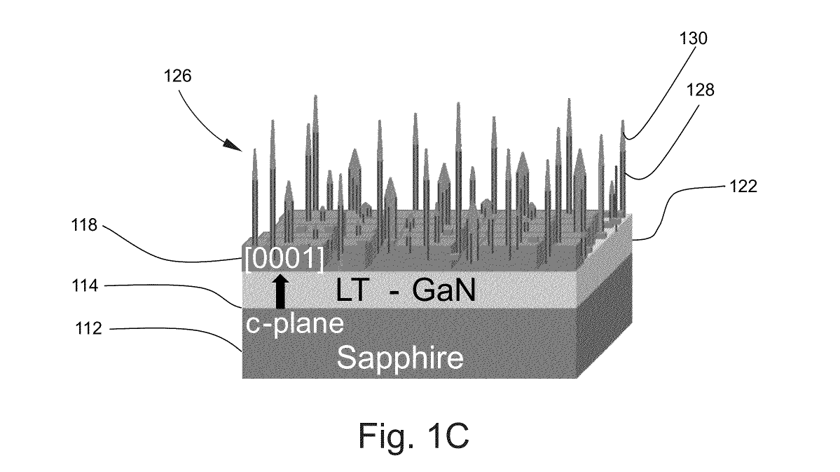

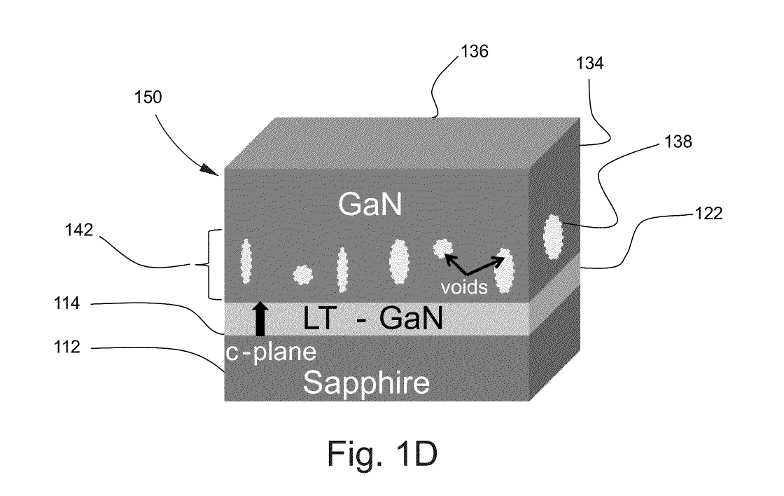

FIGS. 1A-1D illustrate an example of a method for fabricating a GaN-based structure or article (or GaN-inclusive structure or article) according to the present teachings. Specifically, FIGS. 1A-1D are schematic cross-sectional views of the GaN-based structure during various stages of fabrication. For purposes of description, a growth direction (or thickness direction) is depicted generally by an arrow 104. The growth direction 104 is generally the resultant direction in which GaN crystals are grown on an underlying surface to obtain a desired thickness. From the perspective of FIGS. 1A-D, the growth direction 104 is a vertical direction although it will be understood that this orientation is not a limitation of the present teachings. Thicknesses of various layers or regions of materials are typically distances along the growth direction 104. A transverse direction or plane (or lateral direction or plane) is depicted generally by another arrow 108, and is orthogonal to the growth direction 104. Certain surfaces or sides of material layers may be considered as lying in the transverse plane 108, which is horizontal in the present example although this is likewise not a limitation of the present teachings.

Referring to FIG. 1A, a substrate 112 is provided. The substrate 112 includes an upper substrate surface (or growth surface) 114. The substrate 112 may have any composition suitable for heteroepitaxial growth of GaN material on the upper substrate surface 114. Examples of suitable substrate compositions include, but are not limited to, sapphire, silicon, silicon carbide, spinel (MgAl₂O₄), lithium aluminate, lithium gallate, carbon, diamond-like carbon, zinc oxide, magnesium oxide, gallium arsenide, ScAlMgO₄, glass, and aluminum nitride. The substrate 112 may also be GaN, such as relatively thick GaN grown by HVPE, although homoepitaxy from the substrate is not needed for successfully implementing the present subject matter. More generally, the substrate 112 may include various ceramics, glasses, metals, dielectric materials, electrically conductive or insulating polymers, semiconductors, semi-insulating materials, etc. If necessary or desired, steps may be taken to prepare the upper substrate surface 114 for growth of GaN material thereon. Preparation steps may include, for example, planarization of the upper substrate surface 114 by known mechanical means such as lapping, polishing the upper substrate surface 114 such as by chemo-mechanical polishing (CMP), cleaning, dry etching by exposure to plasma, etc. Moreover, the upper substrate surface 114 may have any suitable crystallographic orientation, for example c-plane or a non-polar or semi-polar orientation. Non-polar or semi-polar orientations may be obtained, for example, by slicing the substrate 112 in accordance with known techniques. The substrate 112 may be “provided” by loading the substrate 112 into a reaction chamber in which growth of GaN is effected. The configuration of the reaction chamber will depend on the growth technique or techniques utilized.

The substrate 112 may have any thickness suitable for providing a stable growth platform. Moreover, no limitation is placed on the size of the substrate 112. In this context, “size” may refer to the planar area of the upper substrate surface 114, i.e., the dimensions of the upper substrate surface 114 in the transverse plane 108. In one example, the area ranges from a fraction of an inch squared to about 60 in². In another example, the area ranges from about 1 cm² to about 400 cm². “Size” may also refer to a single characteristic dimension of the upper substrate surface 114 in the transverse plane 108. The characteristic dimension may be taken as the maximum dimension in the transverse plane 108. The nature of the characteristic dimension will depend on the shape or approximate shape of the upper substrate surface 114. For example, if the upper substrate surface 114 is rectilinear the characteristic dimension may be a length, width, etc. of the upper substrate surface 114. As another example, if the upper substrate surface 114 is round (e.g., circular) the characteristic dimension may be a diameter of the upper substrate surface 114. In one example, the upper substrate surface 114 has a characteristic dimension of two inches or greater. In another example, the upper substrate surface 114 has a characteristic dimension of four inches or greater. In another example, the upper substrate surface 114 has a characteristic dimension ranging from a fraction of an inch to about 8 inches. In another example, the upper substrate surface 114 has a characteristic dimension of 1.5 cm or greater. In general, substrate size will be limited by the size and/or capability of the reaction chamber.

After the substrate 112 is prepared and loaded into a reaction chamber, a first GaN layer 118 is grown on the upper substrate surface 114 to a desired thickness. In one example, the thickness of the first GaN layer 118 ranges from 1 to 3 μm. In one example, GaN is grown by metalorganic chemical vapor deposition (MOCVD). The precursor gases include at least one gallium-inclusive gas such as trimethyl gallium (TMGa) or triethyl gallium (TEGa), and at least one nitrogen-inclusive gas such as ammonia (NH₃). As an alternative to MOCVD, other vacuum deposition techniques may be suitable such as, for example, hydride vapor-phase epitaxy (HVPE), molecular beam epitaxy (MBE), or others. If desired, dopants may be added to the GaN of the first GaN layer 118 by any suitable doping technique for the purpose of, for example, producing n-type conductive, p-type conductive or semi-insulating GaN. As examples, silicon or oxygen may be introduced to produce n-type GaN, magnesium may be introduced to produce p-type GaN, or a deep-level acceptor such as a transition metal (e.g., iron, cobalt, nickel, manganese, or zinc) may be introduced to produce semi-insulating GaN. Depending on the growth technique and process conditions, the defect density of the as-grown first GaN layer 118 may be relatively high, for example, 10¹⁰ cm⁻².

As also illustrated in FIG. 1A, if desired or needed, or depending on the composition of the substrate 112 or what is optimal for the particular GaN deposition technique employed, a buffer layer 122 may first be deposited on the upper substrate surface 114 and the first GaN layer 118 subsequently deposited on the buffer layer 122. The buffer layer 122 may serve a specific function such as, for example, reducing the lattice mismatch between the substrate 112 and the epitaxial GaN material 118, or otherwise providing a growth surface more conducive to epitaxial crystal growth. In one non-limiting example, the buffer layer 122 may be aluminum nitride (AlN). AlN may be deposited by, for example, MOCVD at a relative low temperature as appreciated by persons skilled in the art. In other examples, other vapor deposition techniques, as well as physical vapor deposition techniques, and other types of techniques (e.g., thermal evaporation, sublimation, etc.) may be suitable for depositing the buffer layer 122. Other examples of suitable compositions of the buffer layer 122 include, but are not limited to, GaN compositions (e.g, GaN or AlGaN). It will be understood that various implementations of the presently described method may not require a buffer layer 122.

Referring to FIG. 1B, after forming the first GaN layer 118, the GaN crystal of the first GaN layer 118 is utilized to form GaN nanowires 126. This is done by removing portions of the GaN crystal of the first GaN layer 118. The resulting nanowires 126 generally extend upward along the growth direction 104 from exposed areas the upper substrate surface 114 (or surface of the buffer layer 122, if provided), and/or from lowermost regions of the first GaN layer 118 that were not removed by the removal step and thus still cover the upper substrate surface 114 or buffer layer 122. As noted above, the average diameter of nanowires 126 is on the order of nanometers, or tens of nanometers. In one example, the average diameter ranges from 10 to 100 nm. In another example, the average diameter ranges from 20 to 50 nm. In another example, the average diameter is 100 nm or about 100 nm. Generally, the nanowires 126 are distributed over the entire surface area of the substrate 112 (i.e., throughout the transverse plane 108). The distribution may be random. The density of the nanowires 126 over this area may range from, for example, 10⁷ to 10¹⁰ nanowires per cm². The amount of GaN crystal constituting the nanowires 126 may range from, for example, 3 to 10% of the previously grown solid first GaN layer 118. The respective lengths of the nanowires 126 may range from a fraction of the original thickness of the first GaN layer 118 up to the original thickness of the first GaN layer 118. Accordingly, in the present example the average length is on the order of a few microns, i.e., may range from 1 to 3 μm. Each nanowire 126 includes a main section 128 and terminates at a tip section 130. The main section 128 typically constitutes the majority of the length of the nanowire 126 and is the section at which the diameter or other characteristic dimension is specified. The tip section 130 is generally conical and tapers from the main section 128 to an apex, similar to the tip of a needle. The apex is not required to be sharp and may be more in the nature of a dome.

The GaN of the first GaN layer 118 may be removed by any suitable removal technique to form the nanowires 126. In some implementations, the removal technique is an etching technique. In a specific implementation found to work well at present, the nanowires 126 are formed by inductively coupled plasma/reactive ion etching (ICP/RIE) of the first GaN layer 118. The ICP/RIE step is performed in a mask-less process, using suitable etchants such as chlorine (Cl₂) and/or boron trichloride (BCl₃). In some implementations, the etch rate ranges from 0.1 to 0.3 μm/min for GaN and may be higher for AlN.

Referring to FIG. 1C, subsequent to the ICP/RIE (or other type of etching) step the nanowires 126 may be subjected to high-temperature annealing to form distinct non-polar facets on the main sections 128 and semi-polar facets on the tip sections 130 of the nanowires 126.

Referring to FIG. 1D, after forming the nanowires 126, a GaN regrowth step is implemented in which additional GaN is deposited on the substrate 112 and the nanowires 126. As described in more detail below, the deposition of additional GaN results in growth of GaN crystal in the growth direction 104 from exposed (etched) areas the upper substrate surface 114 (or from the surface of the buffer layer 122, if provided), and/or from a lowermost region of the first GaN layer 118 covering the upper substrate surface 114 or buffer layer 122. The deposition of additional GaN also results in growth of GaN crystal from the non-polar and semi-polar facets of the nanowires 126. The GaN crystals growing from the tip regions 130 of the nanowires 126 coalesce to form a continuous second GaN layer 134. The same deposition technique utilized to grow the first GaN layer 118 (e.g., MOCVD) may be utilized to grow the second GaN layer 134. Dopants may also be added to the GaN forming the second GaN layer 134 as noted above. The deposition may continue until a desired thickness for the second GaN layer 134 is obtained.

As also shown in FIG. 1D, the epitaxial overgrowth of the GaN on the nanowires 126 also results in the formation of three-dimensional network of voids 138 in an interfacial region (or dislocation trapping zone) 142 of GaN nearest to the underlying substrate surface 114 (or buffer layer 122), i.e., between the substrate surface 114 (or buffer layer 122) and the continuous second GaN layer 134. The void network is three-dimensional in the sense that the voids 138 are dispersed throughout the planar area of the interfacial region 142 as well as over a distance of the interfacial region 142 in the growth direction 104. In various implementations, the voids 138 may appear to have a honeycomb pattern. In some examples, the thickness of the interfacial region 142 ranges from 0.5 to 3 μm. In another example, the thickness of the interfacial region 142 is 2 μm or about 2 μm. In some examples, the voids 138 have an average length (in the growth direction 104) ranging from 1 to 3 μm. In some examples, the voids 138 have an average characteristic dimension (in the transverse direction 108), e.g. diameter, ranging from 0.1 to 1 μm. More generally, the voids 138 are typically oblong or elongated in the growth direction 104. That is, the length of a given void 138 is typically greater than the characteristic dimension of the void 138, although some voids 138 may be more spherical than ellipsoidal. In some examples, the density of the voids 138 through a transverse plane passing through the interfacial region 142 ranges from 10⁸ to 10⁹ cm⁻². The voids 138 are generally characterized by the absence of crystalline material, with the free surfaces of the voids 138 demarcating the boundaries of the surrounding GaN material. The voids 138 may be filled with residual gases from the GaN deposition process, such as diatomic hydrogen and nitrogen. The voids 138 have been demonstrated to be stable even when subjected to temperatures above 1000° C. As described further below, the voids 138 serve to terminate the excursions of defects that originate below the voids 138 and propagate generally in the growth direction 104 during the GaN deposition and crystal growth processes.

As noted above, after GaN crystals growing from the nanowires 126 coalesce to form the continuous second GaN layer 134, GaN deposition may continue until a desired thickness for the second GaN layer 134 is obtained, thereby forming a GaN-based structure or article 150 as illustrated in FIG. 1D. In some examples, the thickness of the second GaN layer 134 ranges from 3 to 8 μm. As demonstrated by data and discussion provided below, the defect density of the second GaN layer 134 may be much lower than the defect density of the original first GaN layer 118. In some examples, the defect density of the second GaN layer 134, including at an upper surface 136 thereof, is lower than the defect density of the original first GaN layer 118 by three to four orders of magnitude. In some examples, the defect density of the second GaN layer 134 is on the order of 10⁷ cm⁻². In other examples, the defect density of the second GaN layer 134 is on the order of 10⁶ cm⁻². In other examples, the defect density of the second GaN layer 134 is on the order of 10⁶ cm⁻² or less. Therefore, it will be appreciated that the second GaN layer 134 may be provided as a low defect-density, device-ready substrate or template for further fabrication processes. As examples, the second GaN layer 134 may be utilized as a substrate for homoepitaxial growth of bulk GaN material and/or as an active layer of (or substrate for fabrication of) various microelectronic devices, optoelectronic devices, and integrated circuits.

A unique feature of the second GaN layer 134 is that defect density is not only low but also uniformly low. That is, the defect density of the second GaN layer 134 is uniform throughout its structure. Thus, for example, the second GaN layer 134 may have a uniform defect density of 10⁷ cm⁻², meaning that the defect density is 10⁷ cm⁻² across the planar area of the second GaN layer 134, such as may be measured at any randomly selected sub-area (or one or more randomly selected sub-areas) of the second GaN layer 134.

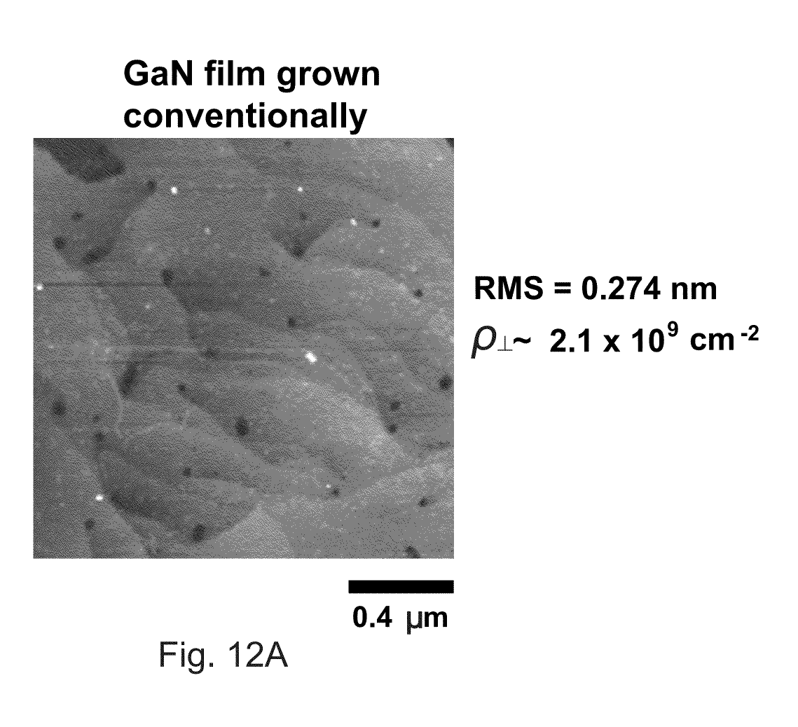

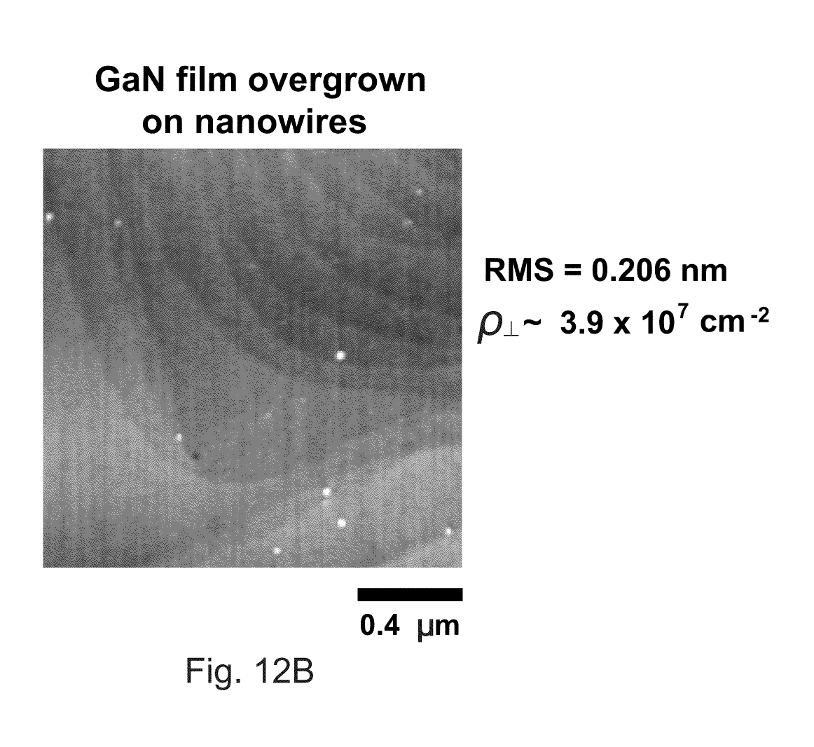

The upper surface 136 of the second GaN layer 134 is smoother than the original surface, i.e., without etching or prior to etching. In one example (FIG. 12B), AFM results showed a surface roughness (RMS) of 0.206 nm of the second GaN layer 134 (after growth from etched nanowires) as compared with 0.274 nm for the original surface (without etching of nanowires) (FIG. 12A).

It will also be noted that the substrate 112, the substrate 112 and the buffer layer 122 (if provided), or the substrate 112, buffer layer 122, and void-containing interfacial region 142, may be removed by any suitable process such as, for example, wet (chemical) etching, dry etching, laser lift-off, rapid cooling or quenching, etc. Another advantage of the void-containing interfacial region 142 is that it significantly facilitates the separation of the underlying substrate 112 from the second GaN layer 134. Accordingly, a GaN-based structure 150 as taught herein may include the free-standing second GaN layer 134 only, or the second GaN layer 134 in combination with one or more of the underlying layers.

In another implementation, the process of void formation and overgrowth may be repeated so as to form more than one level (void-containing interfacial region 142) of voids 138, which may result in a further reduction in defect density in the final second GaN layer 134.

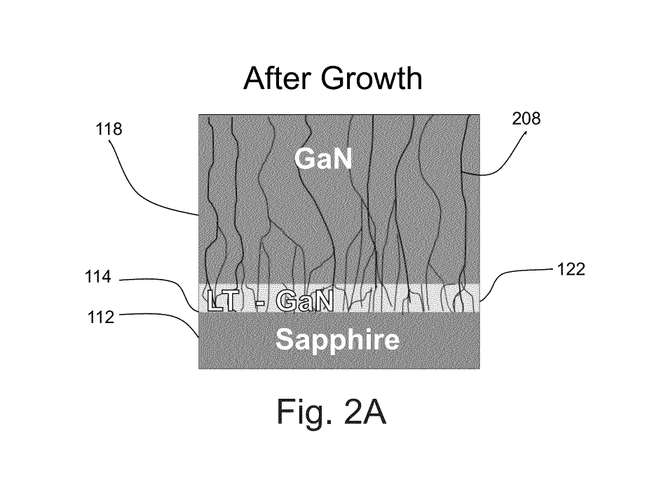

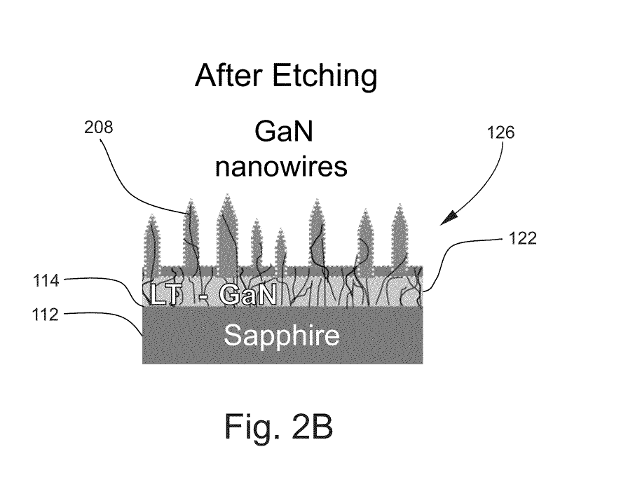

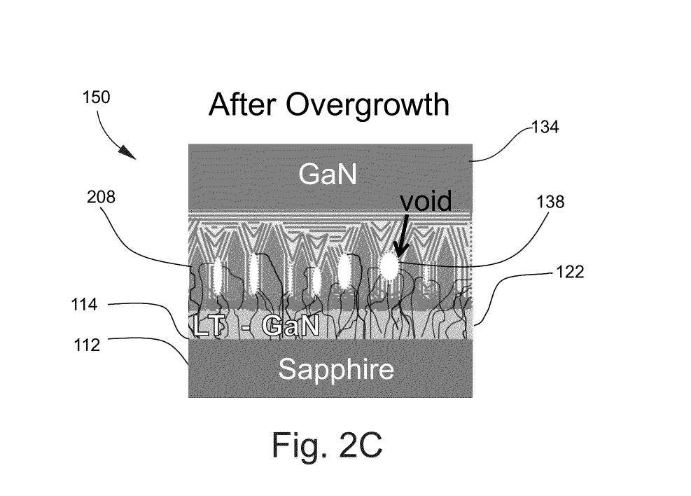

FIGS. 2A-2C are schematic cross-sectional views of the GaN-based structure 150 during various stages of fabrication similar to FIGS. 1A-1D, respectively, but additionally depicting the dislocation configuration of various regions after each stage. Referring to FIG. 2A, a large number of misfit dislocations 208 may be generated at or near the interface of the substrate surface 114 and the first GaN layer 118 (or the buffer layer 122, if provided). These dislocations 208 propagate through the thickness of the first GaN layer 118 as it is grown. Referring to FIG. 2B, the nanowires 126 resulting from mask-less etching (or other type of removal) of the GaN contain some of the as-generated dislocations 208. Referring to FIG. 2C, it can be seen that the network of embedded voids 138 formed during GaN overgrowth from the nanowires 126 serves as a dislocation trapping zone in which the free surfaces of each void 138 act as a dislocation sink for any dislocation 208 generated at or near the epitaxial film/substrate interface. Most or all of the voids 138 are located near the epitaxial film/substrate interface where high densities of dislocations 208 are generated. As schematically depicted in FIG. 2C, almost all of the misfit dislocations 208 generated due to lattice mismatch between the substrate 112 and the GaN compound may be terminated at the free surfaces of the voids 138. A given dislocation 208 may propagate to a void 138 in its vicinity or may be redirected to be trapped in the three-dimensional void network. The result of the trapping effect of the void network is the above-noted significant reduction in defect density in the overgrown GaN layer 134, and a defect density that is highly uniform throughout this GaN layer 134.

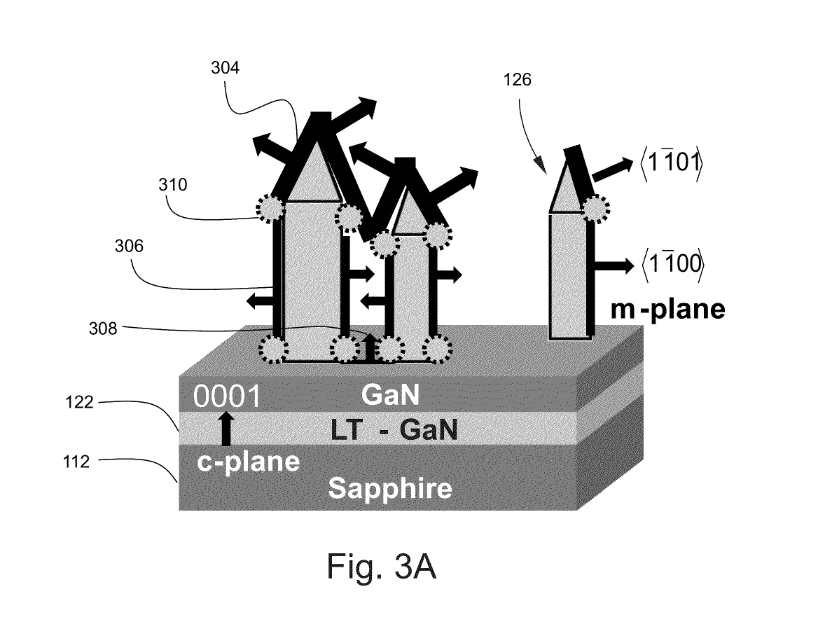

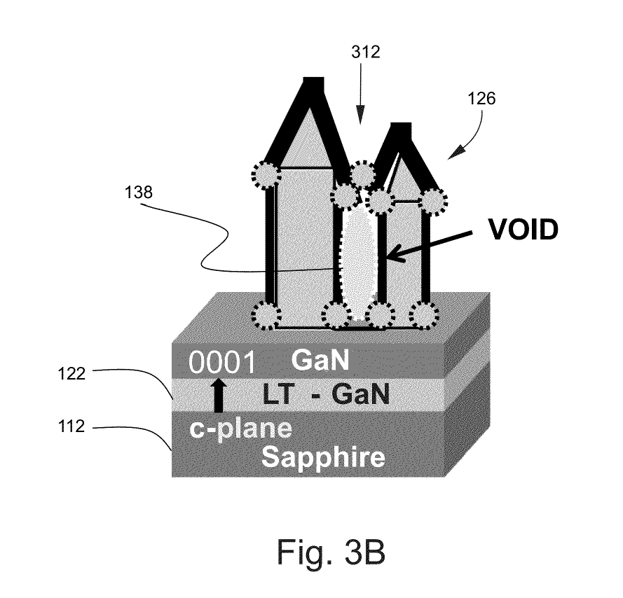

FIGS. 3A and 3B are schematic cross-sectional views illustrating the mechanism by which voids 138 are formed during fabrication of the GaN-based structure. As shown in FIG. 3A, the tip section of each nanowire includes semi-polar {1-101} and {11-22} facets, and the main section of each nanowire includes non-polar {1-100} (m-plane) and {11-20} (a-plane) facets. The transverse plane in this example is taken to be the polar c-plane, or (0001) plane, to which the vertical growth direction is normal. GaN crystal growing from semi-polar {11-22} facets and the angular direction of this growth is indicated at 304 with an accompanying arrow. GaN crystal growing from non-polar {1-100} facets and the lateral direction of this growth is indicated at 306 with an accompanying arrow. GaN crystal growing from the etched c-plane surface (e.g., the areas between the nanowires) and the vertical direction of this growth is indicated at 308 with an accompanying arrow. The GaN crystal 304 growing from the semi-polar facets is schematically depicted as being thicker than the GaN crystal 306 growing from the non-polar facets, which in turn is schematically depicted as being thicker than the GaN crystal 308 growing from the c-plane surface. These relative thicknesses schematically indicate relative growth rates from these facets or surfaces. That is, GaN grows from semi-polar facets at a faster rate than from the non-polar facets, and the growth rate from the c-plane surface may be slower than the growth rate from the non-polar facets. For example, the growth rate on low-order semi-polar planes is about two times faster than on non-polar planes when growing GaN under growth conditions optimized for c-plane growth. FIG. 3A also depicts facet joints 310 (highlighted by asterisks *) where the growth rate is relatively slow.

Thus, it can be seen from FIG. 3A that the growth fronts developing from the semi-polar facets will coalesce before those developing from the non-polar facets. Growth fronts from the semi-polar facets of neighboring nanowires 126 will join to form a V-shaped layer 312 in the 2D projection (a pyramidal cone in the 3D view). Once coalescence from the semi-polar planes and concomitant V-shape formation occur, growth from the non-polar planes and c-plane stops, thereby forming voids 138 between the coalesced nanowires 126. This is illustrated in FIG. 3B, where a void 138 is bounded by the relatively thin crystal grown from etched c-plane surface and non-polar facets of neighboring nanowires 126, and by the underside of adjoined V-shaped crystal 312 grown from semi-polar facets of neighboring nanowires 126. Once the V-shapes (pyramidal cones) are formed, with continued GaN deposition a transition occurs from low-order semi-polar planes to higher-order semi-polar planes such as r-plane {1-102} and {1-106}, and finally to c-plane thereby achieving planarization of the V-shapes (pyramidal cones). This transition and subsequent planarization and vertical growth of the second GaN layer 134 are schematically shown in FIG. 2C.

More generally, the facets from which growth may occur include nonpolar facets such as a-plane {11-20} and m-plane {1-100}, and semipolar facets such as {1-101}, {11-22} and {20-21}.

In an alternative implementation, the voids may be formed by masking and wet etching.

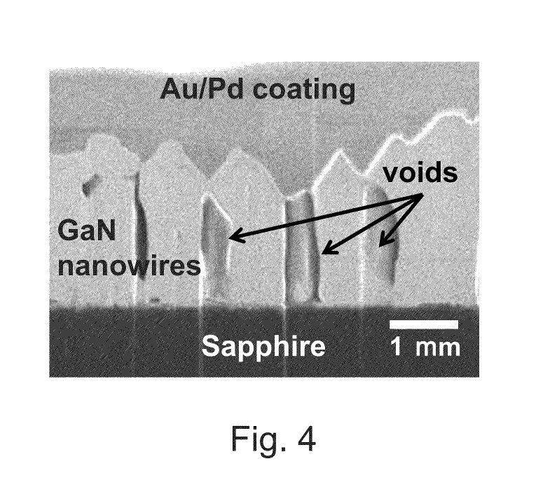

FIG. 4 is a SEM cross-sectional view of a GaN film regrown from GaN nanowires by MOCVD. The nanowires were created by ICP/RIE etching of a GaN film initially grown on a sapphire substrate by MOCVD, in the manner described above. A few of the embedded voids are designated by arrows. A gold/palladium coating was deposited for testing purposes.

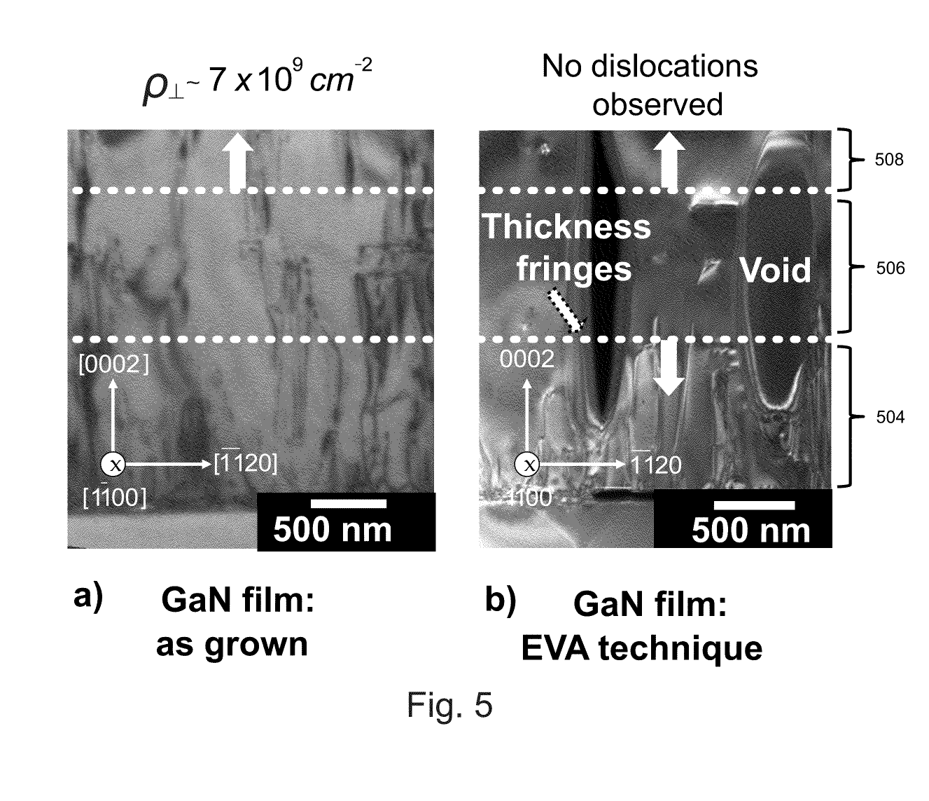

FIG. 5A is a TEM image of a continuous n-GaN film grown on a sapphire substrate by MOCVD. The dislocation density was measured to be about 7×10⁹ cm⁻², which is typical for conventional MOCVD GaN films. By comparison, FIG. 5B is a TEM image of a of n-GaN layer overgrown on n-GaN nanowires. The nanowires were etched from an initial n-GaN film grown on a sapphire substrate in accordance with the above-described method, forming voids below the continuous overgrown n-GaN layer. Dashed lines have been added to FIG. 5B to demarcate three regions in the growth direction: a lower region 504 in which the nanowires extend from the substrate and including the lowermost portions of the voids, an intermediate region 506 including the majority of the length of the voids, and an upper region 508 containing the uppermost portions of the voids. The voids are observed to block dislocations originated near the GaN/sapphire interface. The defect density in the lower region 504 was measured to be about 10¹⁰ cm ⁻². By comparison, no defects were able to be detected in the upper region 508 above the voids. Taking the limitations of the measurement instrumentation and associated measurement techniques into account, it was estimated that the defect density in the overgrown GaN layer is about 10⁷ cm⁻² or less, i.e., no more than 10⁷ cm⁻² and possibly less than 10⁶ cm⁻² in this example. This estimation was supported by two more TEM sample cuts prepared by the focused ion beam (FIB) technique with lengths of 20 μm each. In one specific example, the defect density in a 20×0.16 μm sample was estimated to be about 3×10⁷ cm⁻². Also in these cuts no other defects, such as micro-twins or stacking faults, were observed.

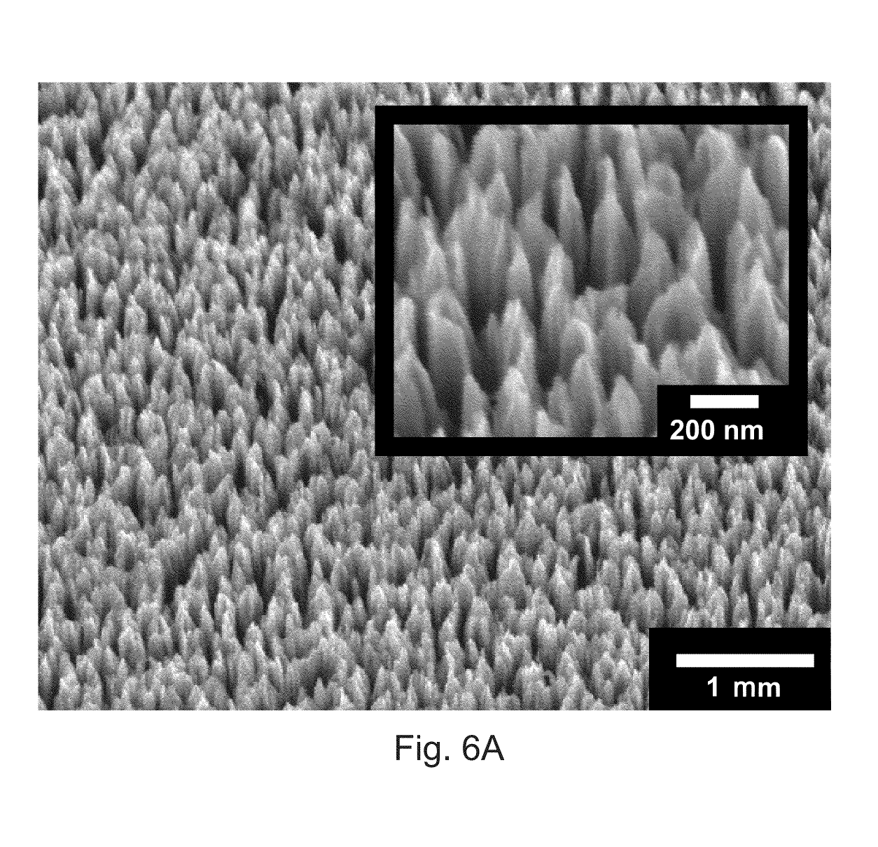

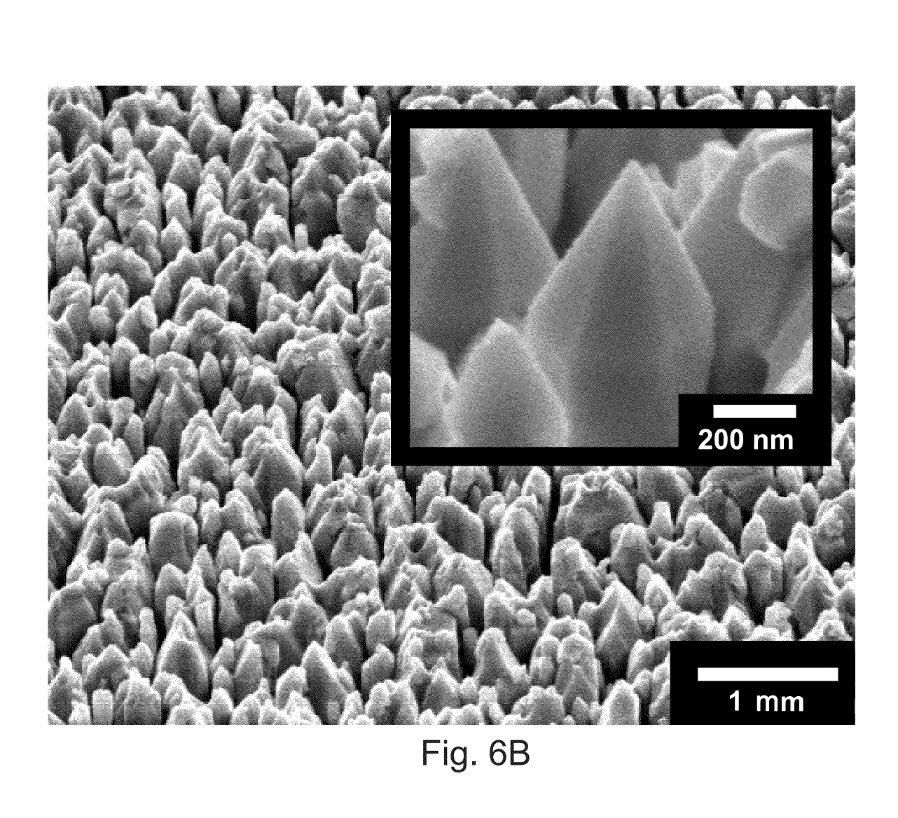

In various examples, the long axis of the as-formed nanowires has been observed to be parallel to the hexagonal GaN c-axis perpendicular to the substrate surface. The tops of the nanowires have been observed to have a hexagonal geometry (i.e., pyramidal shape) of semi-polar facets, which corresponds to the lower order semi-polar planes from non-polar planes, particularly {1-101} from non-polar {1-100} m-plane and {11-22} from non-polar {11-20} a-plane, thus keeping the symmetry of the starting material. FIG. 6A is a high-resolution SEM (HRSEM) image of GaN nanowires formed by mask-less ICP/RIE etching of GaN films grown on sapphire substrates according to the present teachings. FIG. 6B is a high-resolution SEM (HRSEM) image of GaN nanowires after annealing followed by partial GaN overgrowth.

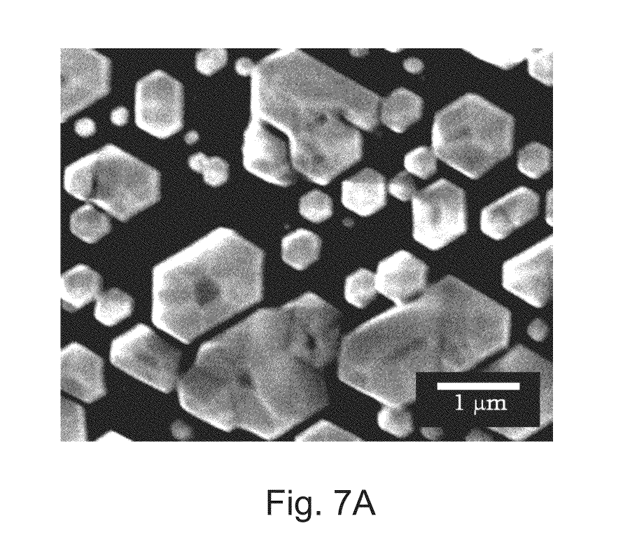

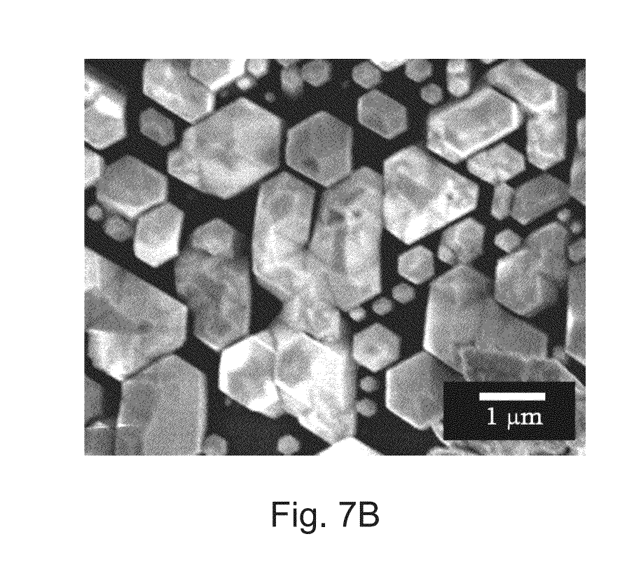

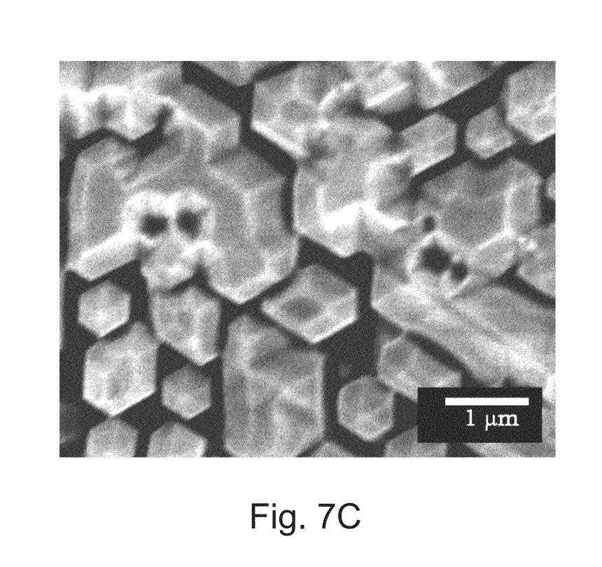

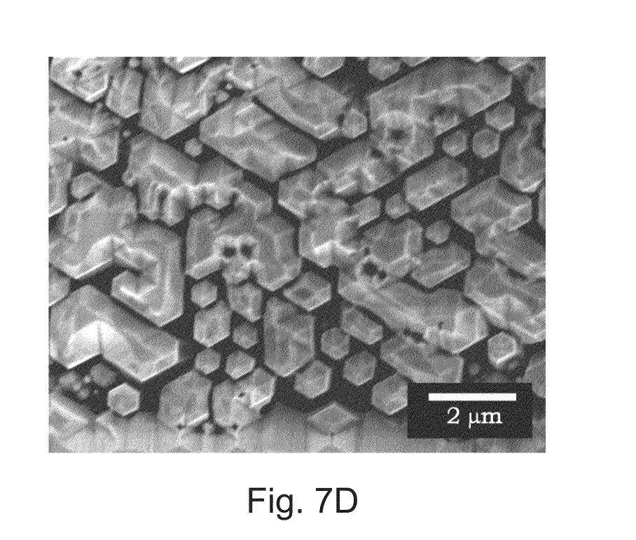

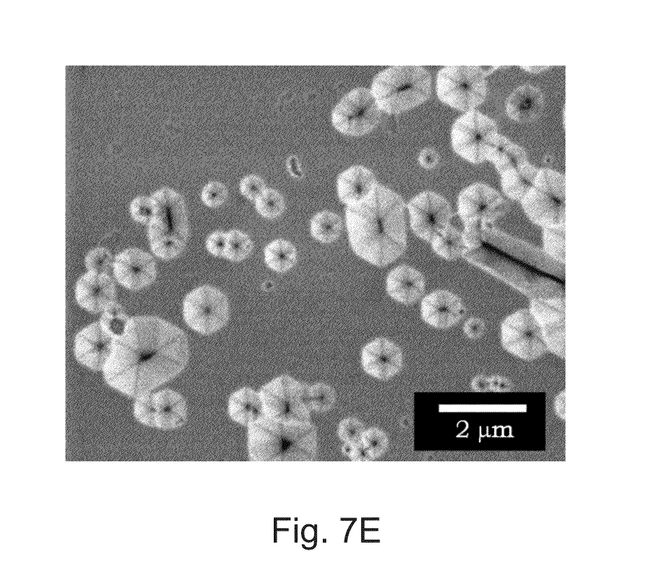

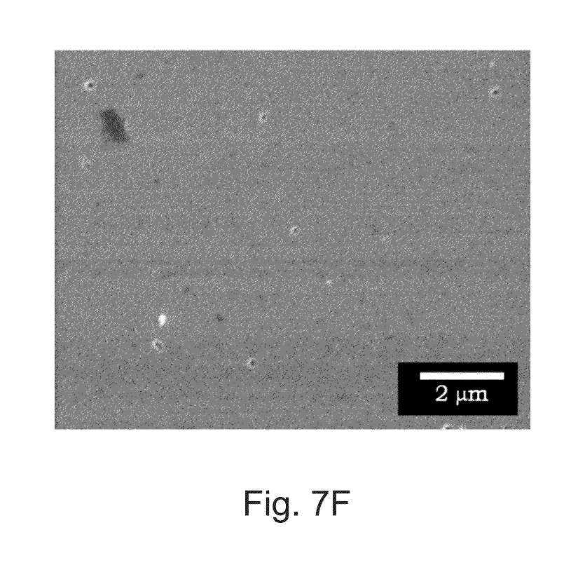

FIGS. 7A-7F are HRSEM images of a sample surface (plane view) showing different growth stages of GaN growing from nanowires. It was observed that the nanowires maintain their initial hexagonal symmetry while growth proceeds from the sidewall facets. Growth continues until the facets of neighboring nanowires coalesce, forming V-shape structures in the 2D projection (pyramidal cones in the 3D view) and trapping voids (as schematically shown in FIGS. 3A and 3B). Planarization of V-shaped structures (pyramidal cones) by high-temperature growth of GaN resulted in templates with very smooth surfaces as shown in FIG. 7F. It thus can be seen that the templates are suitable for fabrication of optoelectronic or microelectronic devices.

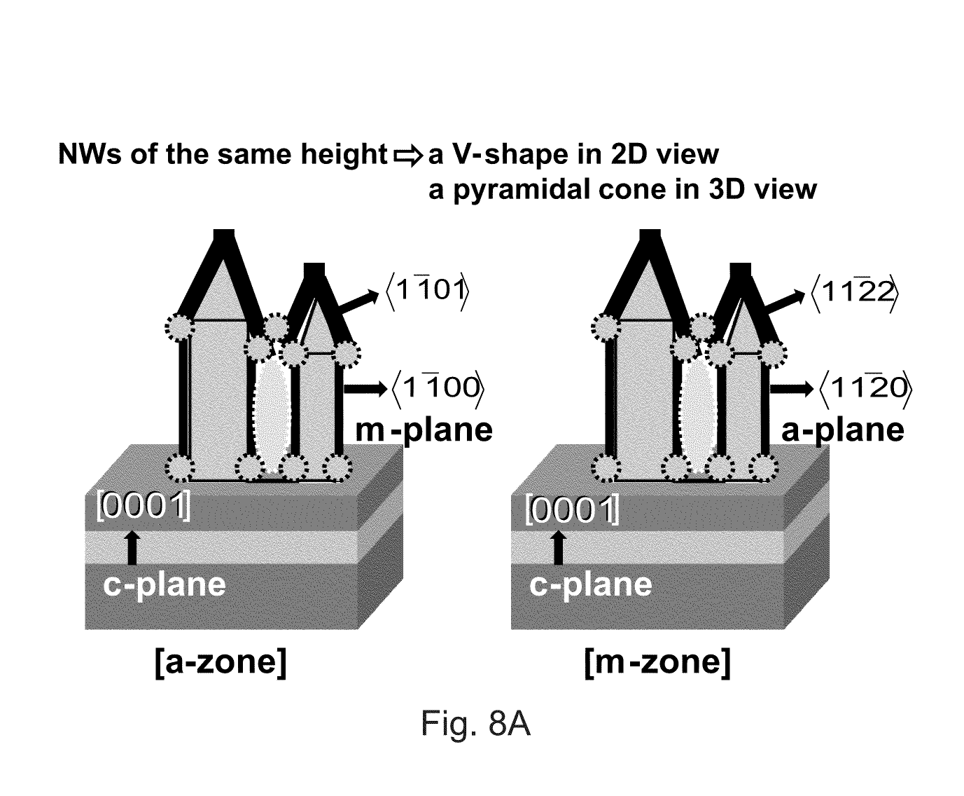

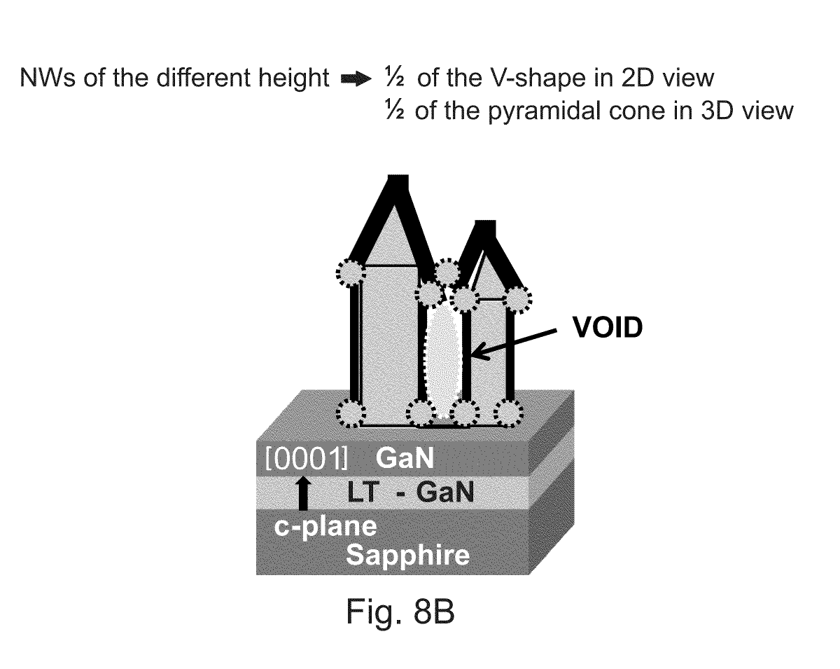

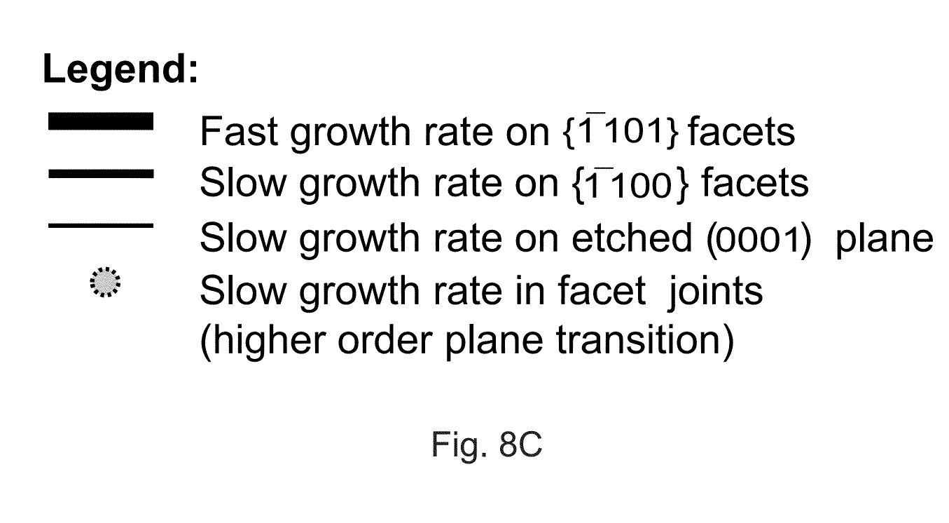

FIG. 8A are schematic cross-sectional views of a GaN-based structure similar to FIG. 3B, illustrating the formation of V-shapes in the 2D projection (pyramidal cones in the 3D view) from different facets of nanowires of substantially the same height. FIG. 8B is a schematic cross-sectional view of a GaN-based structure similar to FIG. 8B, illustrating growth from nanowires of different heights and forming a ½ V-shape in the 2D projection (a ½ pyramidal cone in the 3D view).

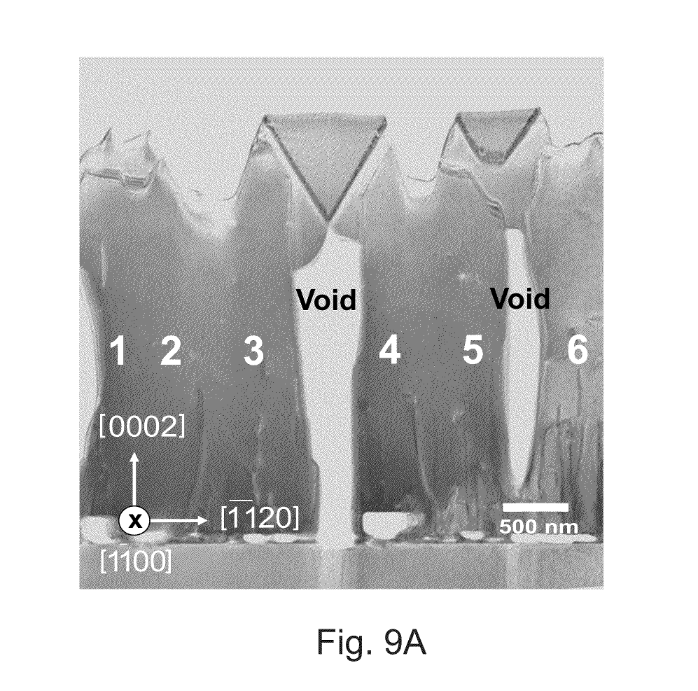

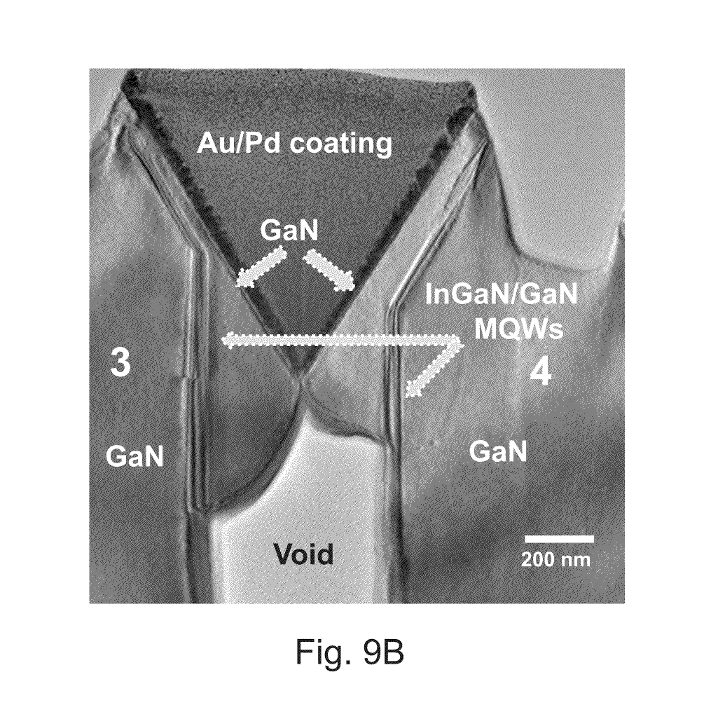

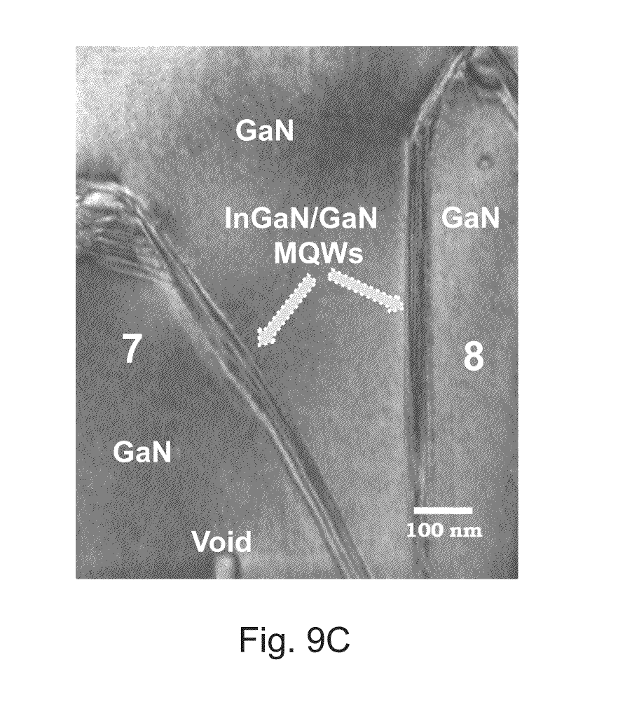

The structural features schematically illustrated in FIGS. 3A, 3B and FIGS. 8A, 8B respectively have also been confirmed by TEM studies of LED structures fabricated from GaN templates provided as taught herein. An example is illustrated in FIGS. 9A-9C, which are bright-field (BF) TEM images in m-plane view (m-zone) illustrating void formation, coalescence between nanowires, and an LED structure on nanowires according to the present teachings and having the following configuration: (p-GaN)/(InGaN/GaN) MQWs/(n-GaN). FIGS. 9A-9B show void formation below the V-groove resulting from coalescence from adjacent n-GaN nanowires. FIG. 9C shows coalescence from the ½ V-shape structure between nanowires of different height. The coalescence did not create any defects. MQW, p-GaN, n-GaN and Au/Pd regions are indicated by labels in FIGS. 9B and 9C.

According to another implementation of the present teachings, an LED is provided, as shown by way of example in FIGS. 9B and 9C. The LED is fabricated from the facets of n-GaN nanowires. In some implementations, InGaN/GaN MQWs are formed on the nanowires followed by deposition of p-GaN material. The nanowire-based LEDs have better photon extraction efficiency than LEDs fabricated from bulk, planar GaN layers. The nanowires present a larger surface area for ,LEDs as compared to planar GaN layers. Thus, photon emission from nanowire-based LEDs is greater than from conventional planar-based LEDs. In one example, photon emission is five times greater. In other implementations, other types of optoelectronic devices are provided, such as photovoltaic devices (e.g., solar cells) and photodetectors. For example, high quality InGaN produced according to the present teachings may be utilized in such devices.

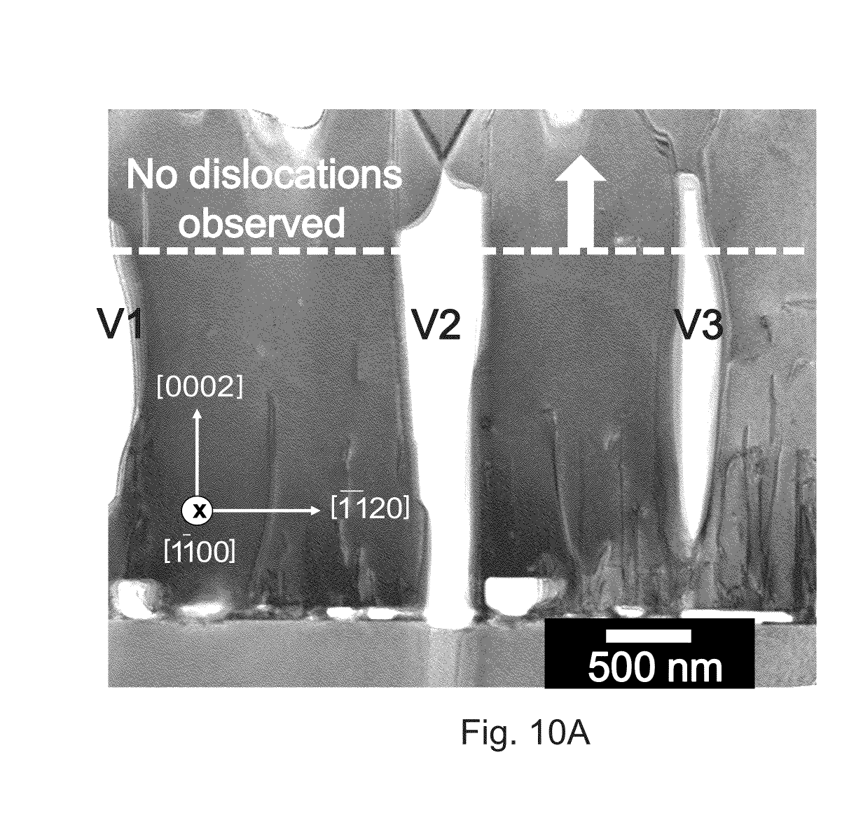

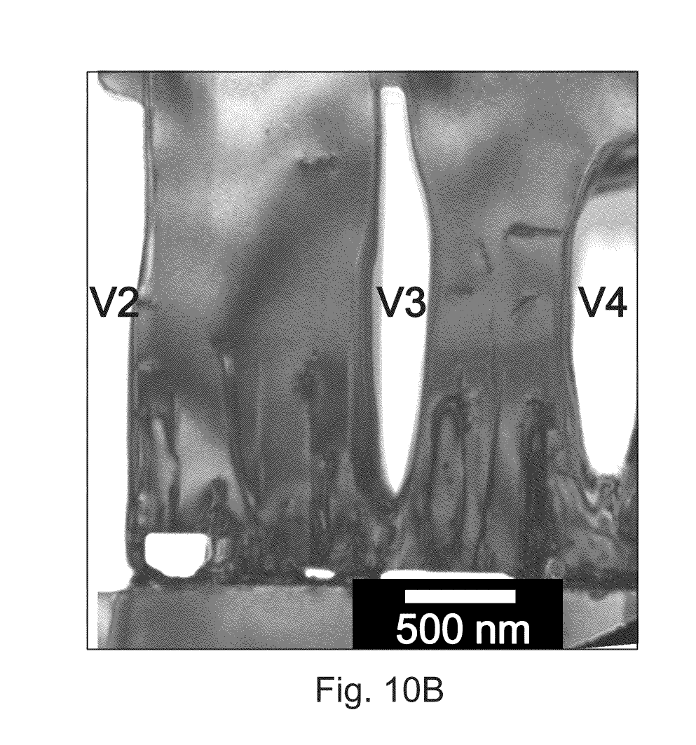

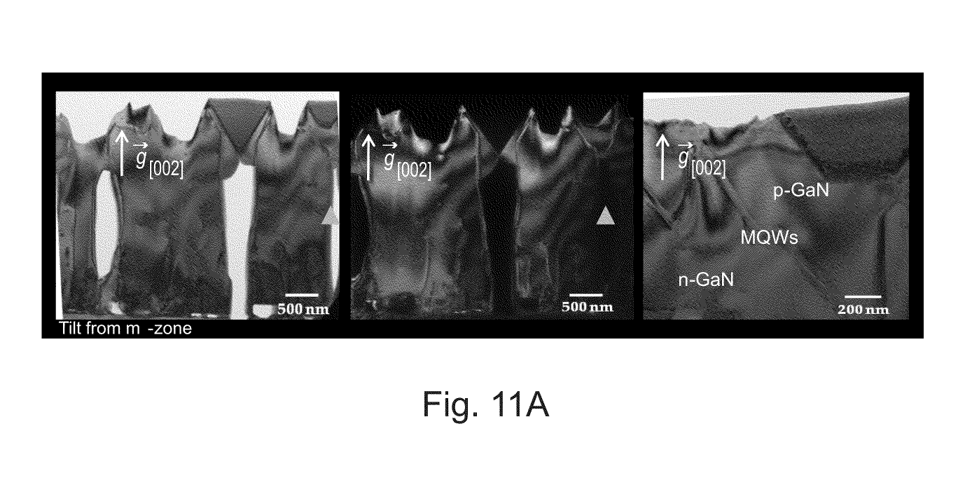

FIGS. 10A and 10B are another set of TEM images showing the formation of voids. No dislocations were observed above the voids.

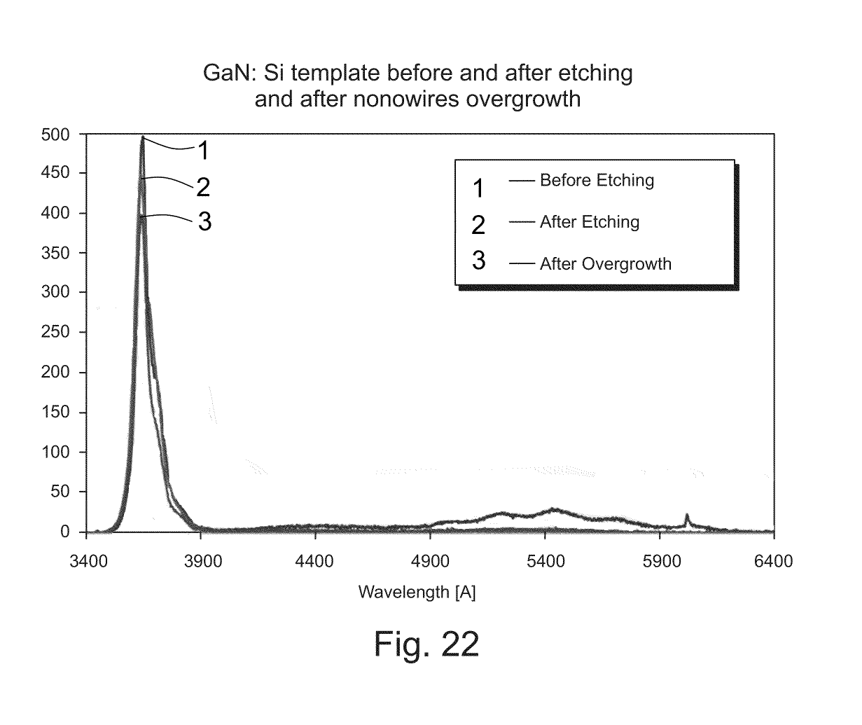

As noted above, the defect density in GaN layers overgrown on nanowires in accordance with the present teachings is estimated to be about 10⁷ or 10⁶ cm⁻² or less. Exact measurements of defect density below 10⁶ cm⁻² are difficult due to the limitations of current measurement technology. Various approaches may be utilized for determining defect density. For example, the atomic force microscopy (AFM) technique has been used extensively to study the density of dislocations in GaN materials. See, e.g., Youlsy APL 74 3537. However, it has been indicated that the AFM technique reveals only screw and mixed dislocations. The technique may not be reliable for imaging edge dislocations. As another example, etch pit count using a hot solution such as KOH or hot phosphoric acid is found to reveal only screw dislocations and the screw component of mixed dislocations. See, e.g., Hang APL 77 82. Additionally, TEM using \vec{g}•\vec{b} analyses (invisibility criteria for pure screw and pure edge dislocations) can reveal the density of pure screw and pure edge dislocations. TEM, however, may not be a reliable technique for measuring dislocation density below 10⁶ cm⁻² at a low magnification of 10,000×, which is considered a very low magnification for TEM performance. XRD line width (FWHM=B) can also be used (see Shen APL 86 021912), based on the formula that dislocation density=αB²/b² where \vec{b} is the Burgers vector that depends on the nature of the dislocations. The XRD line width analysis needs to be carried out on fairly thick GaN films above the thickness of the voids. This is to make sure that the x-ray penetration depth (ξ) of the operating diffraction plane is above the region of the voids, which allows examination of the FWHM of the re-grown GaN layer above the voids. From the TEM studies, the presence of strain contrast surrounding the region of the voids has been observed. This strain can also affect the FWHM of the x-ray. Other techniques such as cathodoluminescence (CL) and photoluminescence (PL) may also be employed. CL may identify all types of defects including edge dislocations as long as they act as minority carrier traps. PL intensity may provide comparative studies of the level of defects on the macroscopic scale, thus providing macroscopic characterization of the quality of the GaN templates and their suitability for electronic devices. FIG. 22 illustrates photoluminescence (PL) data (intensity in arbitrary units as a function of wavelength in nm) obtained from GaN film as conventionally grown before ICP/RIE etching, from GaN nanowires after etching and from GaN film after total nanowires' overgrowth.

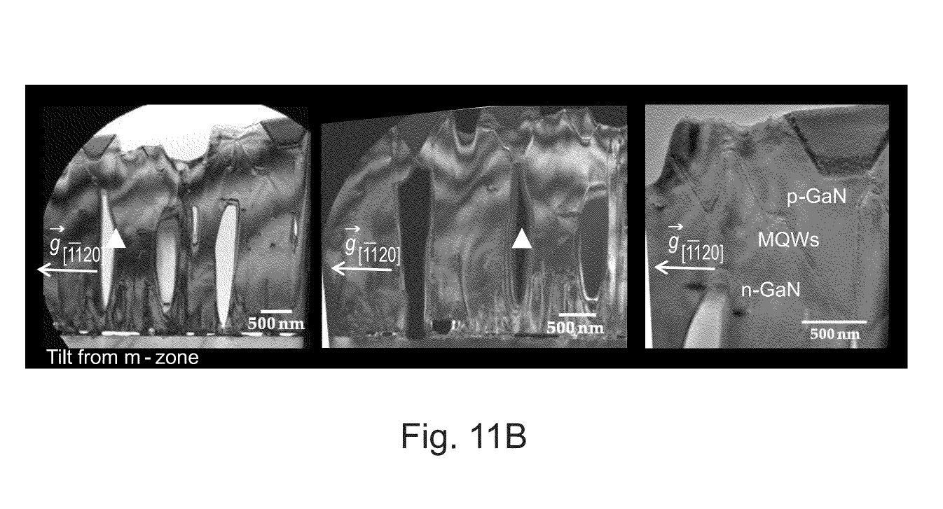

FIGS. 11A and 11B are sets of bright-field (BF) and dark-field (DF) TEM images of GaN films grown on GaN nanowires formed by etching a GaN film initially grown on a sapphire substrate in the manner described above. The TEM samples were prepared by the FIB technique. The TEM images were produced after tilting the sample in the direction of Burgers vectors of pure screw and pure edge dislocations. Specifically, FIG. 11A shows views of the dislocation network with pure screw and mixed dislocations, and FIG. 11B shows views of the dislocation network with pure edge and mixed dislocations. The configuration of dislocations and as-formed voids can be clearly observed from FIGS. 11A and 11B. In the resulting dislocation trapping zone, the voids are several microns in length, range from 200 to 500 nm in diameter, and have a void density of about 10⁸ cm⁻². The random variation in the dimensions of the voids is a result of the variation in the height and diameter of the etched nanowires. Below the voids and close to the substrate, the estimated threading dislocation density is in the range of 10⁹ to 10¹⁰ cm⁻². FIGS. 11A and 11B clearly demonstrate how both pure screw dislocations (±\vec{b}_{screw}=±\vec{c}= [symbol] 0001 [symbol] ) and edge dislocations (±\vec{b}_{edge}(i)=\vec{a}=⅓ [symbol] 2 1̅ 1̅ 0 [symbol] ; (i=1, 2, 3)) are trapped at the voids' surface. Mixed dislocations are present in both sets of TEM images. FIGS. 11A and 11B also show V-grooves formed at the tips of the voids and the overgrowth mechanism from the V-grooves. The illustrated InGaN/GaN MQWs serve as marker for the re-growth on the nanowires. In some examples, after surface planarization, no type of dislocations (pure screw, pure edge, or mixed) were able to be detected above the voids in several testing areas of the samples. Areas larger than 5×5 microns (TEM samples: two cuts by FIB perpendicular to each other: m-zone view and a-zone view) were tested. Therefore, taking into account the limits of TEM resolution, it may be concluded that the density of dislocations was reduced from about 10¹⁰ cm⁻² at the GaN/sapphire interface to 10⁶ cm⁻² above the voids at the overgrown area, thus resulting in a three orders of magnitude reduction in the dislocation density. Moreover, this reduction in dislocation density appears to occur uniformly across the entire sample, in contrast to known techniques such as LEO and lateral growth in grooves where dislocation density occurs in localized areas only.

In another example, a GaN film with embedded voids produced according to the present disclosure was subjected to AFM, XRD and HRSEM analysis to determine surface roughness and quality of re-grown GaN crystal, in comparison to GaN film grown continuously without the formation of nanowires and voids. FIG. 12A is 1.6×1.6 micron AFM scan from a randomly selected area of the surface of a continuously grown GaN film, while FIG. 12B is a similar AFM scan of the surface of a GaN film with embedded voids as taught herein. For the GaN film shown in FIG. 12A, dislocation density was measured to be about 2.1×10⁹ cm⁻² and surface roughness (RMS) was measured to be 0.274 nm. For the GaN film shown in FIG. 12B, dislocation density was measured to be about 3.9×10⁷ cm⁻² and surface roughness (RMS) was measured to be 0.206 nm. A comparison of FIGS. 12A and 12B thus demonstrates that the GaN film with embedded voids has a smoother surface (improvement of about 25%) and less dislocation density (improvement of greater than one order of magnitude). Both GaN samples were cleaned in HCl for 30 minutes at an elevated temperature (120° C.). Pits in the continuously grown GaN film are clearly observable (FIG. 12A) and may correspond to threading dislocations with screw, mixed or edge characteristics. By comparison, pits in the GaN film with embedded voids are very small (FIG. 12B) and may correspond to threading dislocations with edge characteristics. Edge dislocations often appear by themselves in the form of strings. It is believed that these observations indicate that threading dislocations with edge and mixed character are present in the sample shown in FIG. 12B in the range of less than 10⁷ cm⁻².

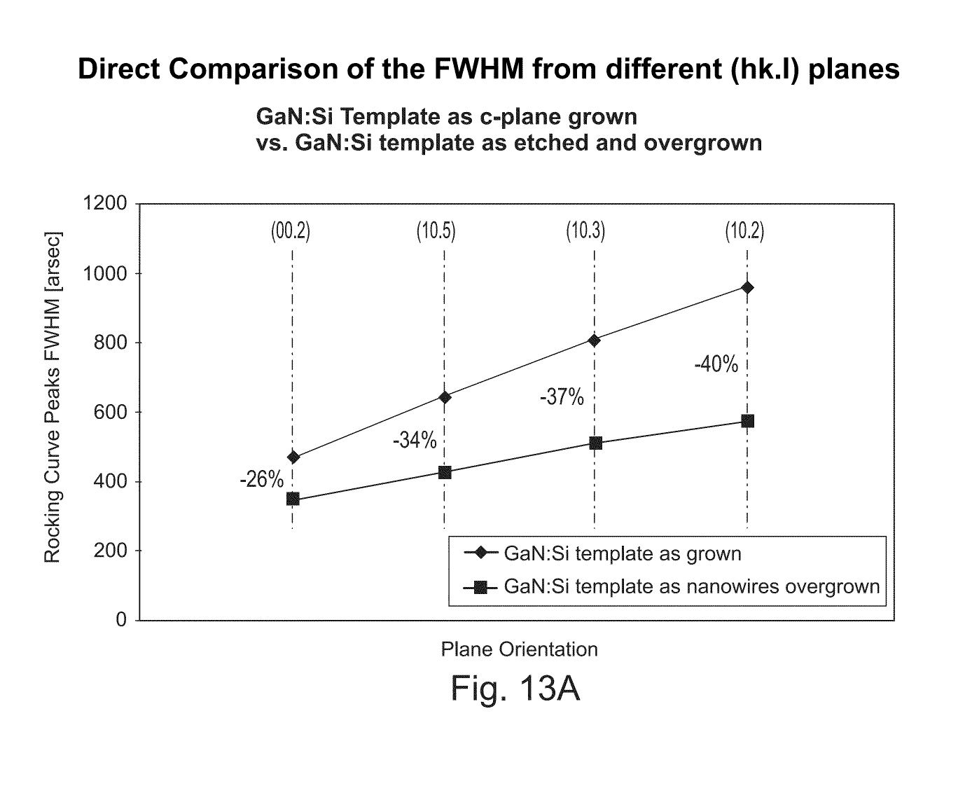

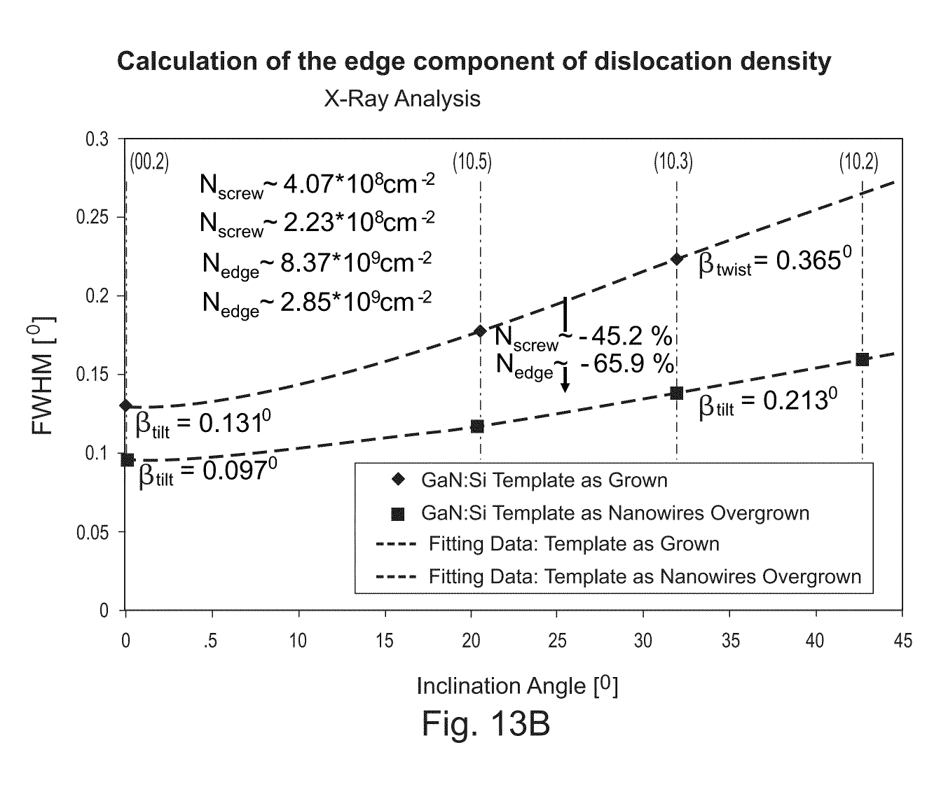

Reduction in dislocation density by embedded voids was further investigated by other techniques as well in order to confirm the estimates of the improvement in GaN film quality. FIG. 13A shows a direct comparison of XRD rocking curve FWHM peaks on different (hk.l) crystallographic planes obtained from continuously grown GaN film and a GaN film with embedded voids. FIG. 13B shows a comparative XRD analysis of a continuously grown GaN film and a GaN film with embedded voids, for calculating both the screw and edge components of dislocation density. Specifically, FIG. 13B contains plots of FWHM of (hk.l) planes as a function of lattice plane inclination angle for the two samples. The XRD measurements were useful for evaluating the crystalline quality of the two GaN films. Tilt (out-of-plane) and twist (in-plane rotation) spreads caused by the mosaicity of the GaN thin films were measured and utilized to estimate the density of threading dislocations. Rocking curves of ω scans of the (00.2), (10.5), (10.3) and (10.2) were measured and the representative results for the ˜2.1-μm thickness GaN films (as continuously grown continuously and as re-grown with embedded voids) are shown in FIGS. 13A and 13B. The reduction of threading dislocations with screw and edge character for the GaN film with embedded voids was confirmed based on calculations of threading dislocation densities from values for tilt and twist angles estimated from the rocking curve FWHMs.

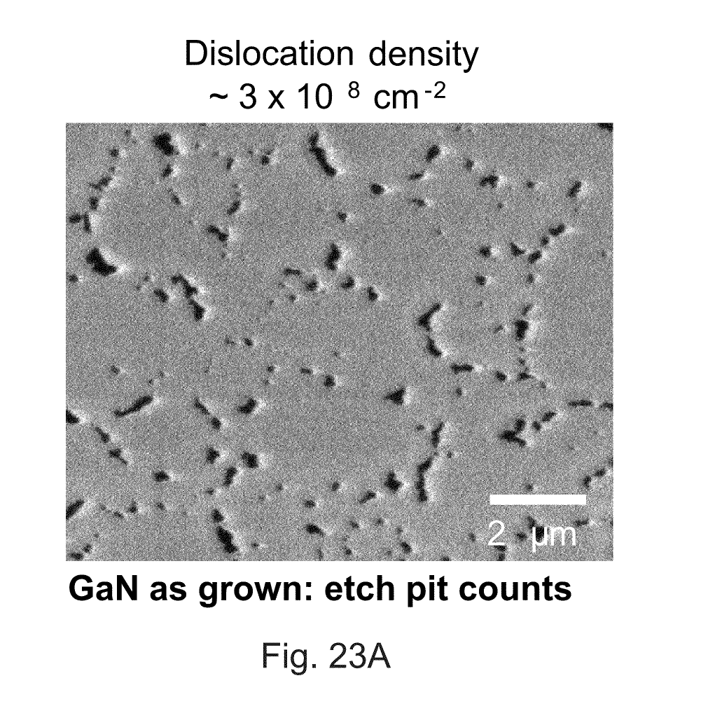

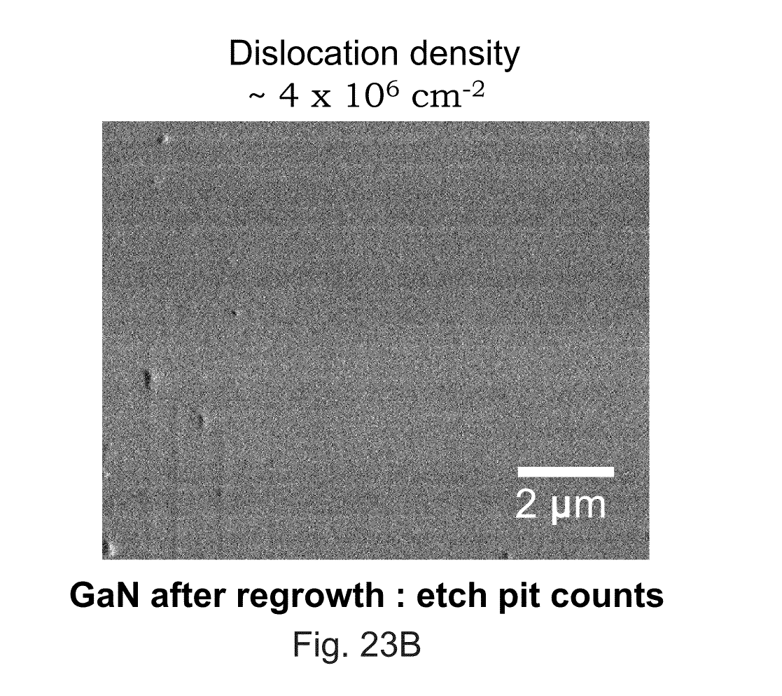

The estimated values of threading dislocations are in good agreement with data obtained from AFM in the case of the continuously grown GaN film. The GaN film with embedded voids shows improvement based on the calculation of threading dislocations. Nevertheless, the calculated values are much higher than were observed by the AFM technique. It will be noted that the XRD technique applied to GaN films with embedded voids could distort results because the embedded voids may cause tilt and twist spreads depending on penetration depth of X-rays. To show distortion of XRD and prove that total dislocation density is on the order of ˜10⁸/cm² or less, a combination of wet etching by H₃PO₄ (solution 85%) and the HRSEM characterization technique was utilized. Both GaN films were etched by H₃PO₄ at 180° C. for 15 minutes and then surface images of both films at the same conditions were captured by HRSEM as shown in FIGS. 23A and 23B. Because the HRSEM technique enables the scanning and mapping of bigger areas of the thin film surface, representative areas were selected from each sample after a few scans. The HRSEM study confirmed the hypothesis that dislocation density in total was significantly reduced and that the estimated dislocation density in the range of ˜10⁶/cm² was achieved. The dislocation density of the GaN as grown was found to be about 3×10⁸ cm⁻² as shown in FIG. 23A, while the dislocation density of the re-grown GaN was found to be about 4×10⁶ cm⁻² as shown in FIG. 23B. Furthermore, the concept of the technique taught herein was confirmed by additional TEM, AFM, XRD and HRSEM studies.

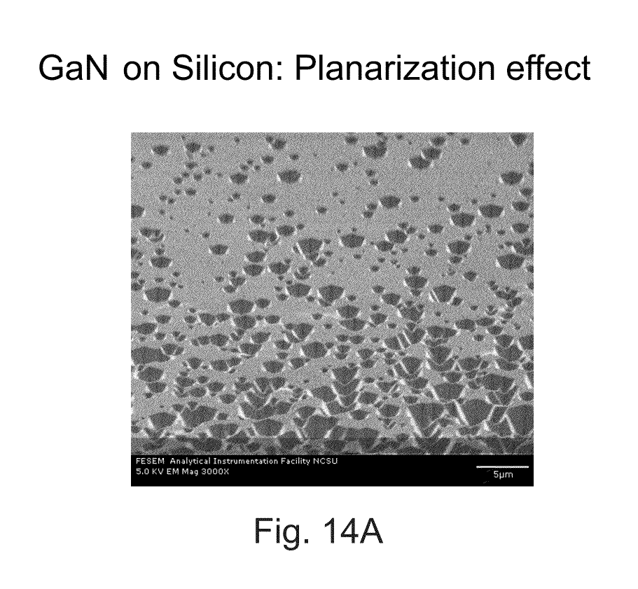

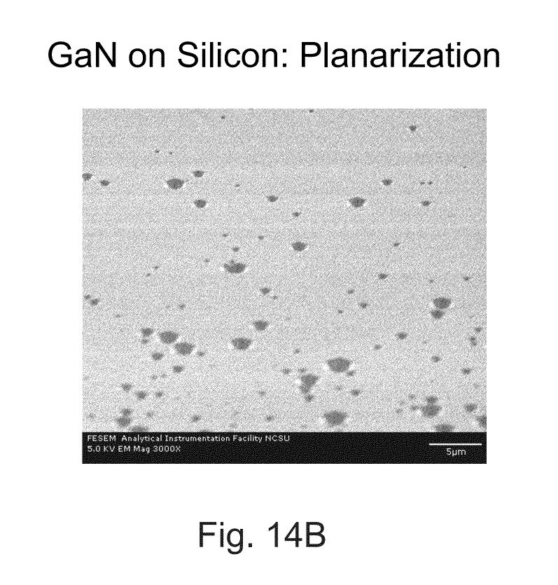

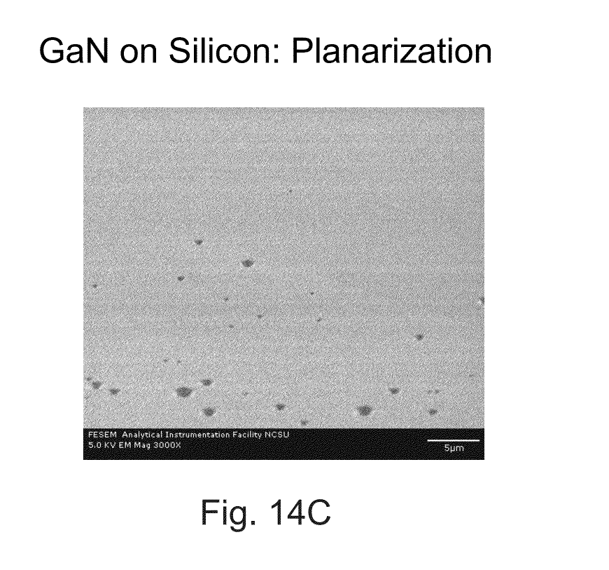

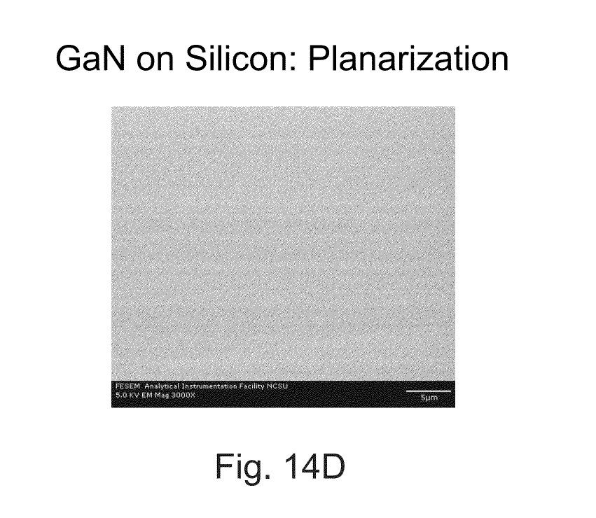

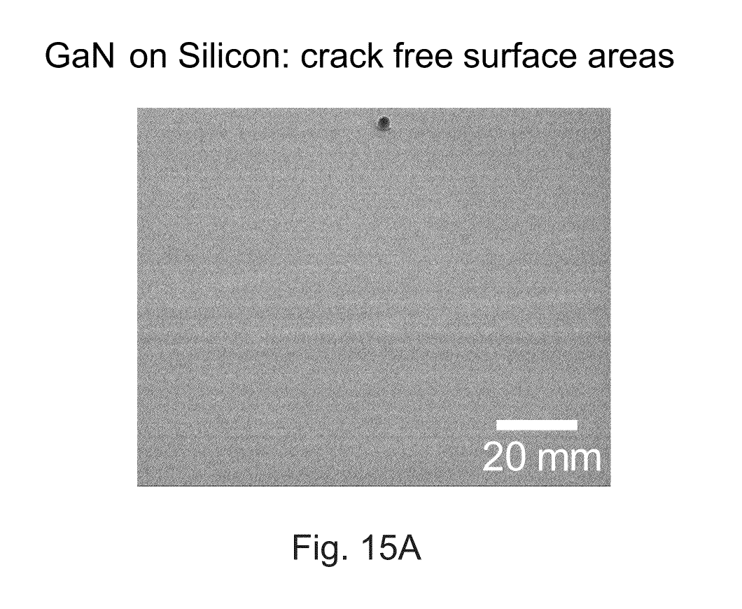

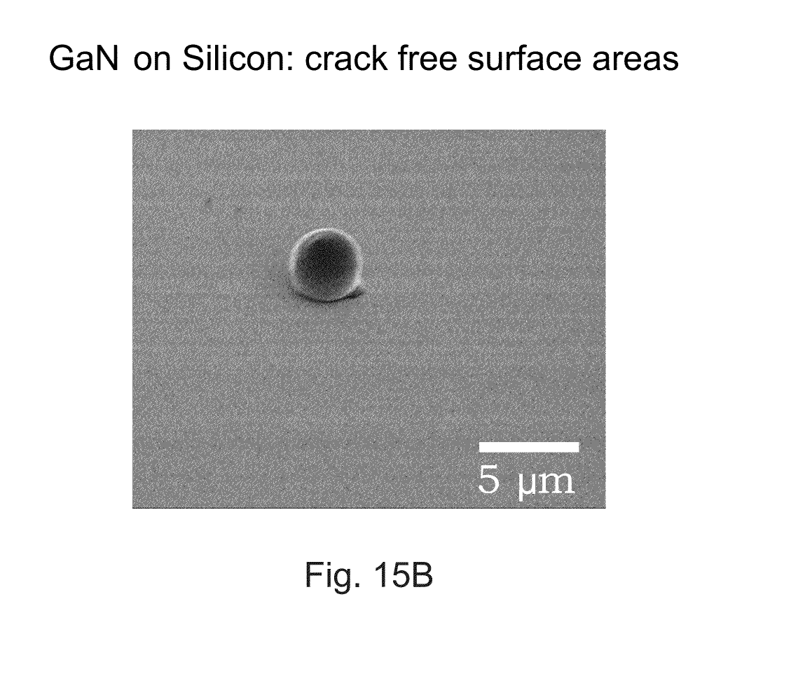

It will be noted that similar results may be achieved even with the use of silicon substrates as opposed to substrates more conventionally utilized for growth of GaN such as sapphire and silicon carbide. FIGS. 14A-14D are HRSEM images of a GaN film re-grown on nanowires formed from a GaN film initially grown on a silicon substrate, showing the planarization effect. FIGS. 15A and 15B are a pair of HRSEM images (two different magnifications) of a GaN film re-grown on nanowires formed from a GaN film initially grown on a silicon substrate. An essentially pit-free surface morphology is evident.

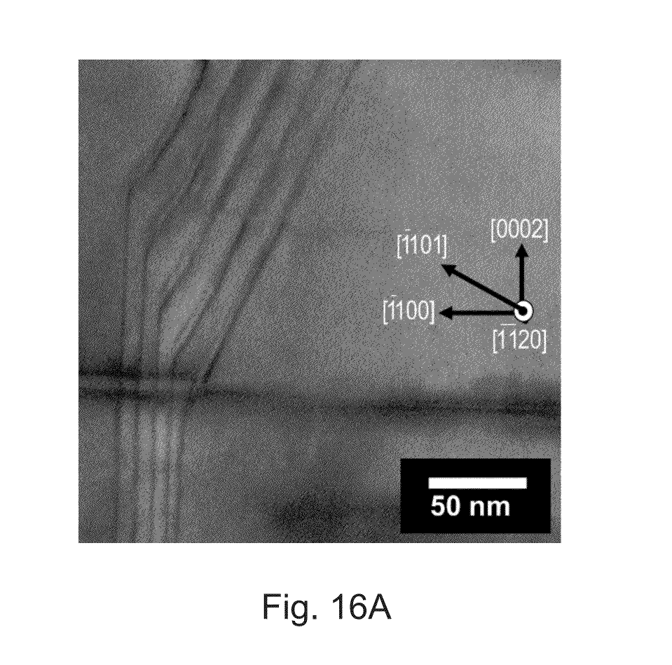

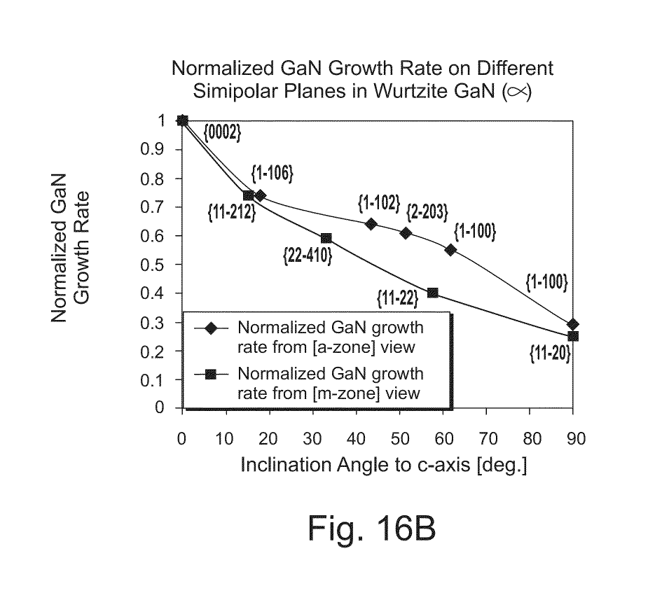

FIG. 16A is a TEM image showing different thicknesses of GaN film overgrowth on a {1-101} semi-polar plane and a {1-100} non-polar m-plane of GaN. FIG. 16B is a graph plotting the normalized growth rate of GaN films on different semi-polar and non-polar planes (facets) according to polar c-plane growth. The inclination angle θ is the angle between the c-direction [0001] and the normal vector to the surface of each particular plane. FIGS. 16A and 16B demonstrate that GaN films grow faster on the {1-101} semi-polar planes than on the {1-100} non-polar planes, which is believed to be an important parameter in the formation of the voids described herein.

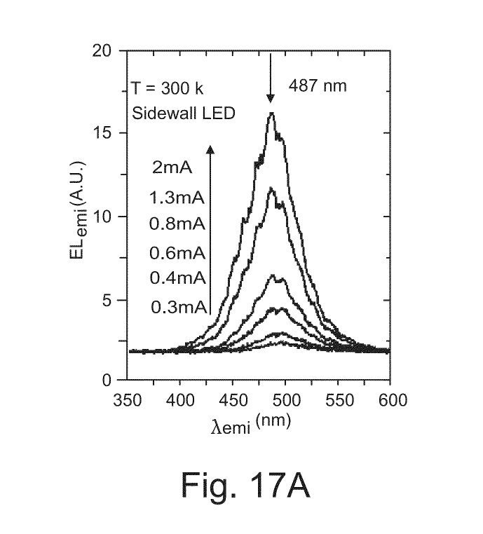

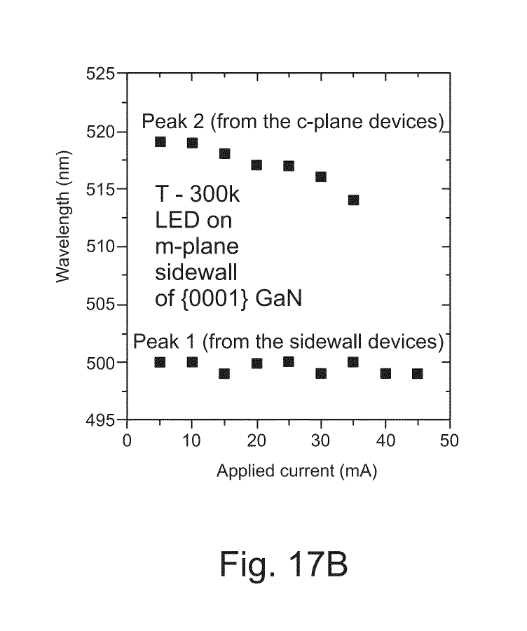

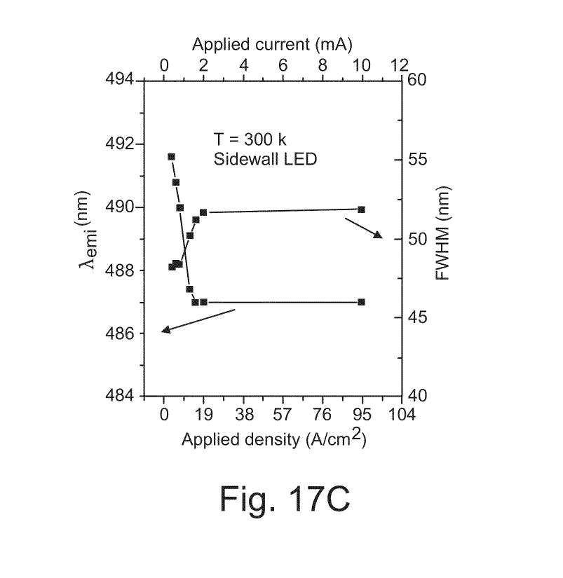

Various devices such as UV LEDs and LDs may be fabricated on non-polar planes. As an example, LEDs may be fabricated by sidewall growth on non-polar or semi-polar planes. Thick GaN films, m-planes {1-100} or a-planes {11-20}, may be etched a few microns deep, followed by sidewall epitaxy of n-GaN/(InGaN/GaN) MQW/p-GaN LED structures. FIG. 17A is set of plots of EL-emission spectrum as a function of wavelength (λ) for various injection current densities. FIG. 17B is a pair of plots of wavelength as a function of applied current for a sidewall-based LED and a c-plane based LED. FIG. 17C is a set of plots showing the relationship between wavelength (λ) (nm), full width at half maxima (FWHM) (nm) and applied current (mA) or applied current density (mA/cm²). The data indicates the absence of quantum-confined Stark effect (QCSE), as the emission wavelength is independent of the current injection levels as demonstrated by FIG. 17C.

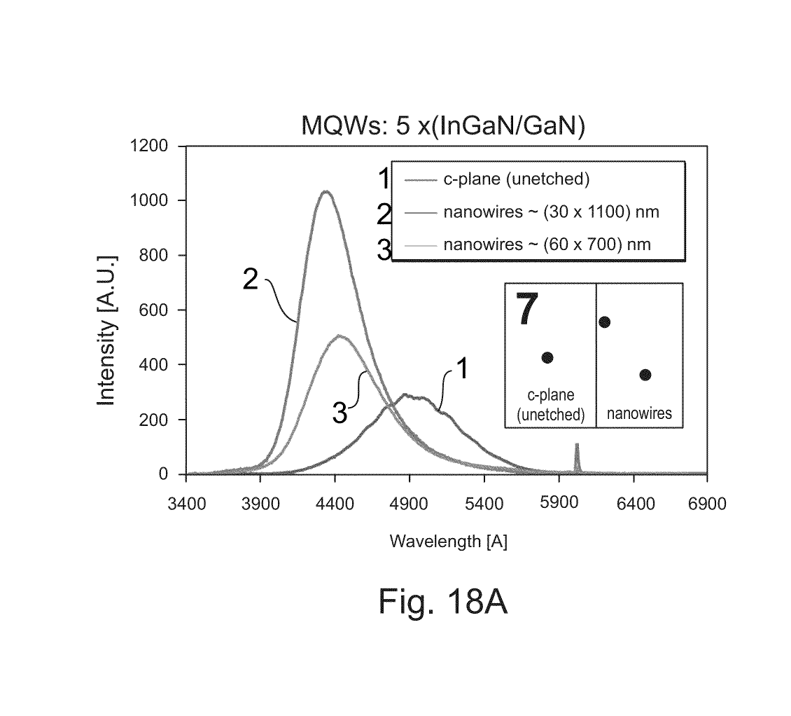

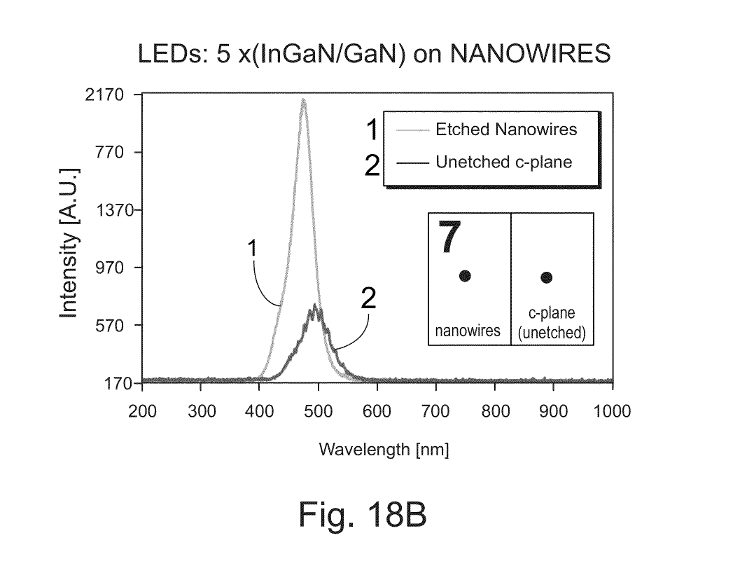

In some examples, LEDs were grown conformally on nanowires similar to those shown in FIG. 6. FIG. 18A illustrates a direct comparison of photoluminescence (PL) (intensity in arbitrary units as a function of wavelength λ in nm) exhibited by a MQWs structure on nanowires (a left half of the experimental sample) versus PL emission of a MQWs structure on unetched c-plane GaN (a right half of the experimental sample) under the same growth conditions. Different wavelength emissions were obtained in those two cases. FIG. 18B illustrates a direct comparison of electroluminescence (EL) emission (intensity in arbitrary units as a function of wavelength λ in nm) exhibited by an LED fabricated on nanowires (a right half of the experimental sample) versus EL emission of an LED fabricated on unetched c-plane GaN (a left half of the experimental sample). Both LED structures have been grown under the same growth conditions within one experimental sample. Different wavelength emissions were obtained in those two cases. The strong PL and EL emissions are a result of GaN/InGaN MQWs grown on n-type GaN (PL) or embedded between n-type GaN and p-type GaN (EL), all grown on sidewalls of the non-polar m-planes and a-planes of these nanowires. FIGS. 18A and 18B demonstrate that the PL and EL emissions from the MQWs and LED structures grown on the nanowires are superior to the MQWs and LED structures grown on the c-plane GaN.

In another example, bulk n-type GaN templates were grown by MOCVD at 350 mtorr. A low-temperature GaN buffer layer of about 100 nm thickness was grown on a sapphire substrate at 475° C. using a TMGa source with a flow of 1.5 sccm (cubic centimeter per minute at STP), followed by annealing and growth of silicon doped GaN (˜2×10¹⁸ cm⁻³) with a total thickness of 2.5 μm at 1000° C. The maskless ICP-RIE technique was utilized with a mixture of Cl₂ (27 sccm) and BCl₃ (5 sccm), etching pressure of 15 mtorr, etching rate of about 213 nm/min and ICP/RIE powers of 300/100 Watts, respectively. Overgrowth on the nanowires was initiated at 1000° C. by growth of n-GaN (˜10¹⁸ cm⁻³) for twenty minutes, followed by the conformal growth of five InₓGa₁₋ₓN/GaN quantum well (x˜0.2) quantum wells at 660/690° C. A magnesium (Mg) doped Al_{y}Ga_{1-y}N (y˜0.2) blocking layer and p-type GaN:Mg (˜10¹⁷ cm⁻³) were then grown for two minutes and 15 minutes, respectively. The p-type film was completely coalescent on the nanowires. During overgrowth, a constant ammonia flow of 1.25 l/min and TMGa, triethylgallium, trimethylindium, trimethylaluminum, cyclopentadienyl magnesium flow of 3.25, 4.80, 54.00, 4.80 and 31.00 sccm were employed, respectively. To provide a comparison, on several samples half of the bulk n-GaN template was covered with a piece of sapphire to act as a mask during the ICP-RIE process to protect a reference c-plane area.

The LEDs formed on the nanowires were found to have improved light extraction efficiency (C_{extraction}) in comparison to the simultaneously grown c-plane LEDs, as reported by Frajtag et al., Improved light-emitting diode performance by conformal overgrowth of multiple quantum wells and fully coalesced p-type GaN on GaN nanowires, Applied Physics Letters 98, 143104 (2011), the content of which is incorporated by reference herein. The LEDs formed on the nanowires can thus be expected to exhibit improved external quantum efficiency (ηₑₓₜ) in view of the relation ηₑₓₜ=ηᵢₙₜ×C_{extraction}, where ηᵢₙₜ is the internal quantum efficiency.

EL data showed that the EL spectrum of the nanowire multi-quantum wells (MQWs) was broader than that of the c-plane MQWs. Also, for the same current injection level, the light output intensity was more than three times larger in the nanowire MQWs as compared to the c-plane MQWs, which may be due to several factors. The first factor is a reduction in defect density by about 2-3 orders of magnitude in the film overgrown on nanowires. Reduction in defect density improves the radiative/non-radiative lifetime ratio, which impacts ηᵢₙₜ. The second factor is the larger surface area of the MQWs conformally grown on the nanowires. Based on TEM results, emission originates from the quantum wells on the low-order semipolar planes {1-101} and {11-22}, and from the higher-order semipolar planes such as {2-203}, {1-102}, {1-106} and {11-24}, in both [a-zone] and [m-zone] views. MQWs on the semipolar planes will have an effective area larger than that of the c-plane. The third factor is the absence or minimization of the quantum confined Stark effect (QCSE) resulting from the overgrowth of the MQWs on semipolar and nonpolar plane facets of the n-GaN nanowires. This results in a better overlap of the electron and hole wave functions, and enhances the optical power output relative to that on the polar c-plane LED.

The fourth factor is the presence of the embedded voids which can improve the light extraction process. Light escape cones are governed by a critical angle, θ_{c}, which depends on the refractive indices. Light outside the escape cone is repeatedly reflected into the GaN film and then re-absorbed by the active layer or metal contacts, unless the light escapes through the side walls of the device. A waveguide, created by these voids, will help channel the emitted photons to be incident on the GaN/sapphire substrate with angles less than the critical angle for total internal reflection (TIR). In other words, the emitted light, due to the presence of the voids, has a higher chance of being within the escape cone. The EL spectral data suggested the occurrence of Fabry-Perot multiple reflections, which can be correlated with multiple reflections between the top and bottom surfaces of the GaN. Such features are not present in the c-plane LED and can be related to the presence of these waveguides. The embedded voids may be characterized as forming scattering regions, or wave guided regions, which reduce the probabilities of photons impinging at angles larger than θ_{c}.

In some implementations, fabrication of the LED device entails removing the substrate and adding (e.g., attaching or adhering) a heat sink in the place of the removed substrate. The heat sink is typically opaque or light-absorptive. In such implementations, the voids may serve to increase light extraction from the top region of the LED device.

It will be noted that in addition to UV LEDs and LDs, LEDs in the visible range may be fabricated by sidewall growth on non-polar facets of GaN nanowires in accordance with the techniques disclosed herein.

In addition to significant reduction in defect density, the three-dimensional network of embedded voids provides significant thermal stress relief. The degree of thermal stress relief is particularly advantageous because it enables growth of high-quality GaN crystal on silicon substrates as well as more conventional substrates such as sapphire and silicon carbide. In particular, high-quality GaN films may be grown without the occurrence of cracking and bowing typically associated with growth on silicon substrates. Therefore readily available, low-cost silicon substrates may be utilized in the fabrication of device-quality LEDs and other optoelectronic and microelectronic devices.

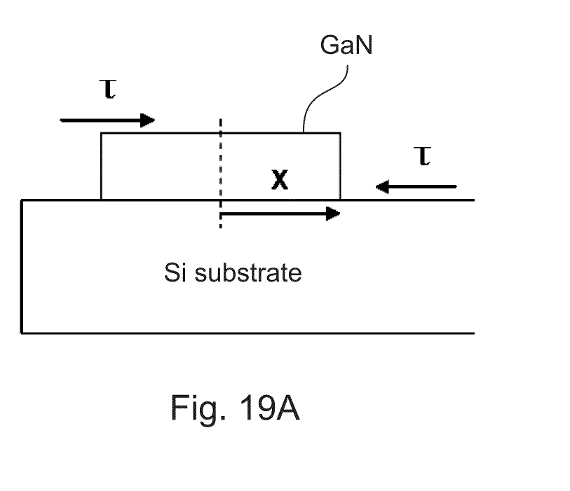

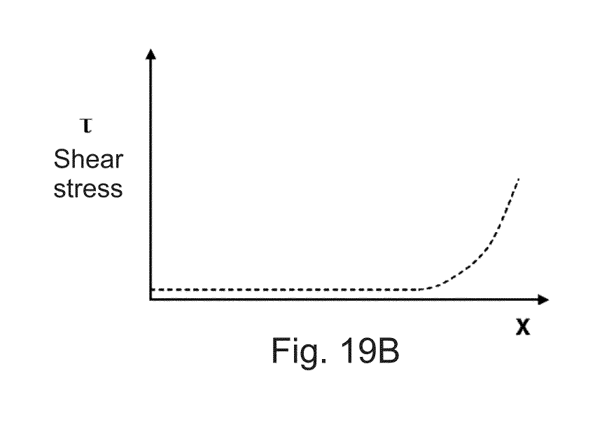

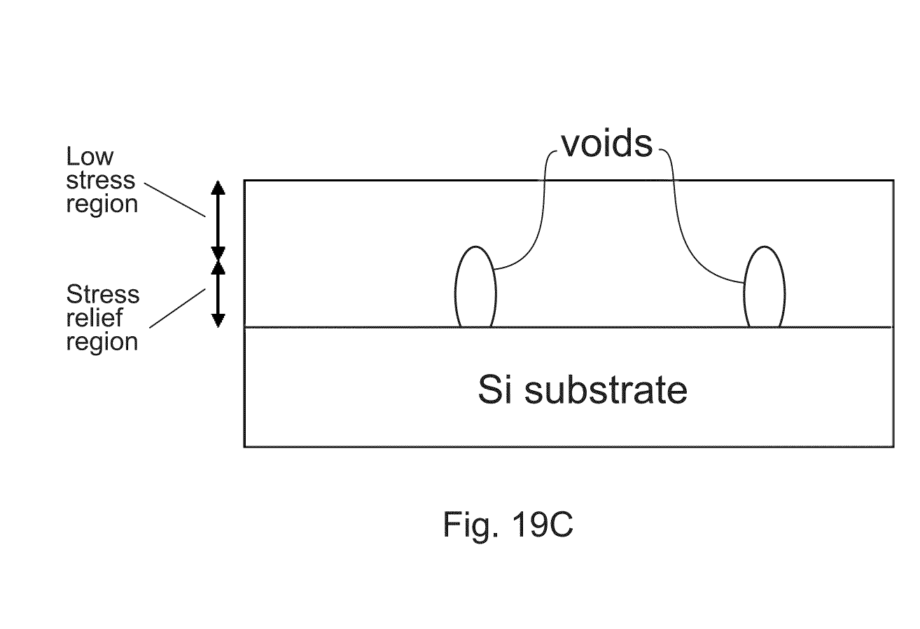

It is known that shear stresses at the GaN/Si interface due to the difference in thermal expansion coefficients will exert bending moments that result in cracking when these stresses exceed the mechanical strength of GaN. The value of these stresses increases with the dimension of the GaN film. This is illustrated schematically in FIG. 19. Specifically, FIG. 19A depicts shear stress τ acting on a GaN film deposited on a silicon substrate, and FIG. 19B plots shear stress as a function on the dimension x depicted in FIG. 19A. It can be shown that for GaN islands with dimensions in tens of microns, the epitaxial layer will be exposed to almost zero shear stress, even for a thick (greater than several microns) GaN film on a silicon substrate. The value of the shear stress, τ, increases with the distance, x, in a one-dimensional model showing for small dimensional structures values of τ are practically negligible. The embedded void approach offers a solution to this problem. FIG. 19C is a schematic cross-sectional view of a GaN film on a silicon substrate, where the GaN film includes a network of voids generated as disclosed herein. In addition to serving as a defect trapping zone, the voids function as a stress relief region. The continuous GaN film re-grown from nanowires (above the void-containing stress relief region) may be characterized as a low-stress region of GaN film. The high density of voids generates regions that are GaN free, thus realizing the selective area growth which avoids cracking.

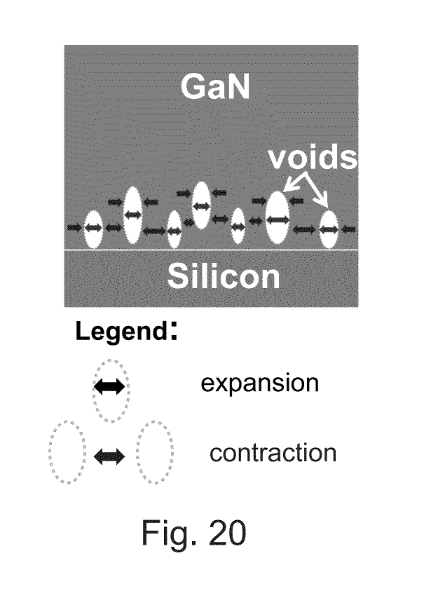

The stress relief mechanism provided by the voids is further depicted in FIG. 20, which is a schematic cross-sectional view of a GaN film on a silicon substrate in which expansion of the voids is depicted by arrows and contraction of the voids is depicted by other arrows. The voids may be characterized as acting as expansion joints in the GaN epifilm. The voids offer the stress relief mechanism needed to avoid cracking and bowing. Accordingly, the voids facilitate the formation of thick, low stress and low defect density GaN grown on silicon substrates.

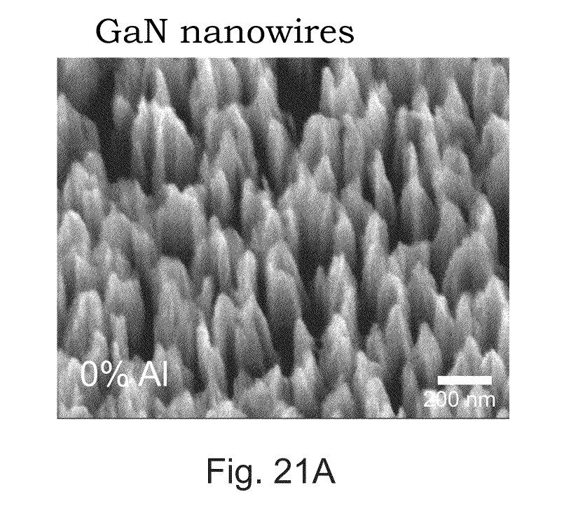

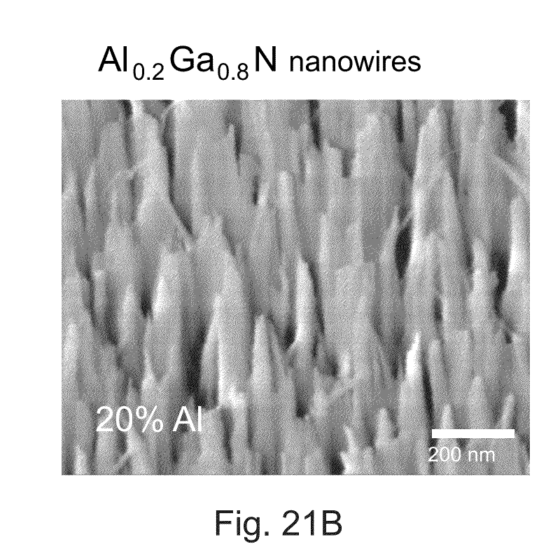

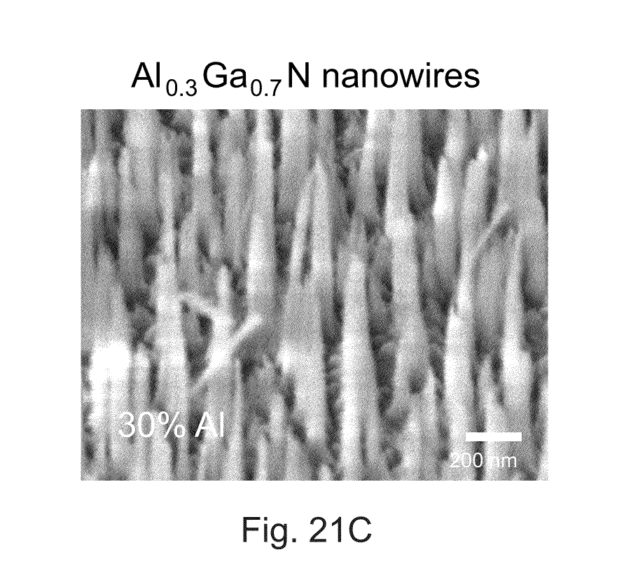

FIGS. 21A-21C are high-resolution SEM (HRSEM) images of GaN nanowires, respectively having different contents of Al (AlₓGa₁₋ₓN where 0<x<1), specifically 0% Al, 20% Al and 30% Al, formed by mask-less ICP/RIE etching of GaN films grown on sapphire substrates according to the present teachings.

FIG. 22 illustrates photoluminescence (PL) data (intensity in arbitrary units as a function of wavelength in nm) obtained from GaN film as conventionally grown before ICP/RIE etching, from GaN nanowires after etching and from GaN film after total nanowires' overgrowth.

It will be evident that the methods disclosed herein and the low-defect GaN material fabricated thereby according to the present teachings may provide one or more advantages. For example, the methods are very effective for reducing defect density. The high-density network of embedded voids formed by the technique is able to trap almost all edge, screw and mixed dislocations in the GaN films. The etching process may be optimized to attain the high-density void network, thus providing a highly effective dislocation trapping process. Defect reduction by a factor as high as 10³ (three orders of magnitude) has been demonstrated. A significant amount of the defects generated in the originally grown film template, which serves as the platform for forming the nanowires, is removed during the slow etching undertaken to form the nanowires. The subsequent regrowth of GaN material on these high-quality nanowires also helps to minimize defects. Moreover, defects are reduced uniformly across the entire wafer area. Uniform defect reduction has not been achieved utilizing known techniques such as, for example, LEO and lateral overgrowth in trenches which result in regions of high and low defect densities.

Additionally, the nanowires may be formed by an etching technique that does not require the use of lithography processes, and does not require growth of the nanowires and the attendant growth conditions (which would be difficult to control). Alternatively, nanowires may be formed by self-assembly, which may or may not be followed with slight etching. Also, both non-polar and semi-polar GaN templates may be successfully fabricated utilizing the methods disclosed herein. The quality of the GaN templates overgrown on the nanowires is not presently believed to critically depend on the properties of the starting GaN films (before etching and formation of voids). Thus, for example, large-area sapphire substrates oriented for growth of non-polar or semi-polar planes such as m-planes or a-planes may be utilized for the growth of GaN templates with low defect density. Also, the composition of the GaN template is tunable for different optoelectronic applications. For instance, when fabricating a UV emitter the percentage content of Al in the GaN template may vary to obtain sensitivity to a desired UV wavelength. The etching process (e.g., ICP-RIE) may be calibrated as needed for producing GaN material with different percentage content of Al. In addition, the presently disclosed technique has a high degree of scalability. For example, a uniformly low defect-density GaN film can be grown on substrates having diameters of four inches or larger. There is no limitation on the size of the substrate other than the constraints of the particular deposition technology utilized (e.g., the MOCVD reactor).

Additionally, the voids serve as a buffer layer that very effectively accommodates thermal mismatch between the GaN material and the underlying substrate, thereby greatly increasing the variety of substrates that may be utilized. In one advantageous example, the presently disclosed technique is readily adaptable to epitaxial growth on widely available, low-cost, large-area silicon substrates. No limitation is placed on the size of the silicon substrate utilized in the presently disclosed technique. One non-limiting example is commercially available six-inch silicon substrates. As appreciated by persons skilled in the art, the use of large-area silicon substrates would result in a significant reduction in epitaxy costs, including better production yield considering that larger substrates corresponds to fewer devices formed near edges of the wafer. Moreover, the higher thermal conductivity of silicon will produce more uniform wafers. For instance, the thermal conductivity ratio of silicon to sapphire is κ_{silicon}/κₛₐₚₚₕᵢᵣₑ=2.6, and thus devices fabricated on a silicon substrate are expected to yield a 20% reduction in wavelength spread due to reduced temperature variations, for example, Δλ/ΔT=˜1.5 to 2.0 nm/° C. Additionally, the use of silicon substrates is expected to result in better run to run reproducibility. Because silicon, unlike sapphire, is opaque in the spectral region in which IR thermometers operate, optical pyrometers can be utilized much more effectively to control run to run temperature variations.

Additionally, the voids provide enhanced light transmission properties as described above.

In view of the foregoing, it can be seen that the GaN templates and associated methods disclosed herein are advantageous for fabricating a wide variety of optoelectronic devices such as LEDs, LDs, solid state lighting (SSL) devices, UV detectors, photocells, photovoltaic devices (e.g., solar cell), solar-blind detectors, flat-panel displays and other display devices, chromogenic devices, optical MEMS devices and other optoelectronic devices, as well as microelectronic devices such as non-light-emitting diodes, transistor-based devices such as high electron mobility transistors (HEMTs), field effect transistors (FETs), etc. The low-defect GaN crystal resulting overgrowth on nanowires as taught herein may enable better performance of such devices.

The methods disclosed herein may be applied to other material systems, one non-limiting example being gallium arsenide (GaAs) on a silicon substrate.

In general, terms such as “communicate” and “in . . . communication with” (for example, a first component “communicates with” or “is in communication with” a second component) are used herein to indicate a structural, functional, mechanical, electrical, signal, optical, magnetic, electromagnetic, ionic or fluidic relationship between two or more components or elements. As such, the fact that one component is said to communicate with a second component is not intended to exclude the possibility that additional components may be present between, and/or operatively associated or engaged with, the first and second components.

It will be understood that various aspects or details of the invention may be changed without departing from the scope of the invention. Furthermore, the foregoing description is for the purpose of illustration only, and not for the purpose of limitation—the invention being defined by the claims.

1. A gallium nitride-based structure, comprising:
a substrate comprising a growth surface;
a first layer of gallium nitride disposed on the growth surface, the first gallium nitride layer comprising an interfacial region proximate to the growth surface and a plurality of voids dispersed in the interfacial region; and
a second gallium nitride layer disposed on the first gallium nitride layer and having a defect density lower than a defect density of the gallium nitride of the interfacial region.

2.-3. (canceled)

4. The gallium nitride-based structure of claim 1, comprising a buffer layer disposed on the growth surface, wherein the first gallium nitride layer is disposed on the buffer layer.

5. The gallium nitride-based structure of claim 4, wherein the buffer layer has a composition selected from the group consisting of aluminum nitride and gallium nitride.

6. (canceled)

7. The gallium nitride-based structure of claim 1, wherein the voids contain one or more gases selected from the group consisting of hydrogen, nitrogen, and both hydrogen and nitrogen.

8. The gallium nitride-based structure of claim 1, wherein the interfacial region has a void density ranging from 10⁷ to 10¹⁰ cm⁻² in a plane normal to a thickness direction of the gallium nitride-based structure.

9. The gallium nitride-based structure of claim 1, wherein the voids have an average length ranging from 0.2 to 5 μm in a thickness direction of the gallium nitride-based structure.

10. The gallium nitride-based structure of claim 1, wherein the voids have an average characteristic dimension ranging from 0.1 to 1 μm or less in a direction normal to a thickness direction of the gallium nitride-based structure.

11. (canceled)

12. gallium nitride-based structure of claim 1, wherein the voids have an average length in a thickness direction of the gallium nitride-based structure and an average characteristic dimension in a direction normal to the thickness direction, and the average length is greater than the average characteristic dimension.

13. (canceled)

14. The gallium nitride-based structure of claim 1, wherein the defect density of the second gallium nitride layer is uniform throughout an area of the second gallium nitride layer normal to a thickness direction of the gallium nitride-based structure.

15. The gallium nitride-based structure of claim 1, wherein the defect density of the second gallium nitride layer is selected from the group consisting of a defect density on the order of 10⁷ cm⁻², a defect density on the order of 10⁶ cm⁻², and a defect density on the order of 10⁶ cm⁻² or less.

16.-18. (canceled)

19. The gallium nitride-based structure of claim 1, wherein the defect density of the second gallium nitride layer is less than the defect density of the interfacial region by at least three orders of magnitude, or by at least four orders of magnitude.

20.-21. (canceled)

22. The gallium nitride-based structure of claim 1, wherein the second gallium nitride layer is disposed on the first gallium nitride layer at a faceted interface comprising a plurality of facets of gallium nitride crystal.

23. The gallium nitride-based structure of claim 22, wherein the facets are selected from the group consisting of nonpolar facets, both nonpolar facets and semipolar facets, facets having a {11-20} orientation, facets having a {1-100} orientation, facets having a {1-101} orientation, facets having a {11-22} orientation, facets having a {20-21} orientation, and a combination of two or more of the foregoing.

24. (canceled)

25. A method for fabricating a gallium nitride-based structure, the method comprising:
depositing gallium nitride on a growth surface of a substrate to form a first gallium nitride layer having a thickness in a growth direction;
forming a plurality of gallium nitride nanowires by removing gallium nitride from the first gallium nitride layer such that the gallium nitride nanowires extend from the growth surface along the growth direction and comprise respective tip regions, and the tip regions comprise facets;
depositing additional gallium nitride to grow gallium nitride crystals from the facets, wherein gallium nitride crystals growing from neighboring facets coalesce to form a continuous second gallium nitride layer, and a plurality of voids are dispersed throughout an interfacial region of the first gallium nitride layer between the growth surface and the second gallium nitride layer; and
continuing to deposit the additional gallium nitride until a desired thickness of the second gallium nitride layer is obtained.

26.-30. (canceled)

31. The method of claim 25, wherein the interfacial region has a void density ranging from 10⁷ to 10¹⁰ cm⁻² in a plane normal to the growth direction.

32.-36. (canceled)

37. The method of claim 25, wherein the defect density of the second gallium nitride layer is uniform throughout an area of the second gallium nitride layer normal to the growth direction.

38. The method of claim 25, wherein the defect density of the second gallium nitride layer is selected from the group consisting of a defect density on the order of 10⁷ cm⁻², a defect density on the order of 10⁶ cm⁻², and a defect density on the order of 10⁶ cm⁻² or less.

39.-44. (canceled)

45. The method of claim 25, wherein the facets are selected from the group consisting of nonpolar facets, semipolar facets, both nonpolar facets and semipolar facets, facets having a {111-20} orientation, facets having a {1-100} orientation, facets having a {11-101} orientation, facets having a {11-22} orientation, facets having a {20-21} orientation, and a combination of two or more of the foregoing.

46.-47. (canceled)

48. The method of claim 25, wherein forming the gallium nitride nanowires comprises etching in accordance with a mask-less etching technique.

49. The method of claim 48, wherein mask-less etching technique comprises inductively coupled plasma/reactive ion etching.

50. The method of claim 49, wherein forming the gallium nitride nanowires comprises utilizing an etchant selected from the group consisting of chlorine, boron trichloride, and both chlorine and boron trichloride.

51. The method of claim 48, wherein etching is done at an etch rate ranging from 0.1 to 0.3 μm/min.

52. The method of claim 25, wherein forming the first gallium nitride layer generates dislocations in the first gallium nitride layer, and substantially all of the dislocations terminate at the voids.

53. (canceled)

54. The method of claim 25, wherein depositing the additional gallium nitride comprises growing gallium nitride crystal from non-polar facets of the gallium nitride nanowires, and the growth rate of the gallium nitride crystal from the semi-polar facets is higher than the growth rate of the gallium nitride crystal from the non-polar facets.

55. The method of claim 25, wherein depositing the additional gallium nitride comprises growing gallium nitride crystal from semi-polar facets at a growth rate ranging from 0.01 to 0.08 μm/min.

56. The method of claim 25, wherein depositing the additional gallium nitride is done at a growth temperature ranging from 900 to 1050° C.

57. (canceled)

58. The method of claim 25, wherein the tip regions have a hexagonal geometry.

59. The method of claim 25, wherein the second gallium nitride layer comprises a top surface having a surface roughness ranging from 0.2 to 0.3 nm.

60. The method of claim 25, wherein the amount of gallium nitride comprising the nanowires is 1 to 10% by weight of the amount of gallium nitride comprising the first gallium nitride layer prior to forming the gallium nitride nanowires.

61. The method of claim 25, comprising separating the second gallium nitride layer to form a free-standing gallium nitride layer.

62. A free-standing gallium nitride-based structure fabricated according to the method of claim 61.

63. A gallium nitride-based structure fabricated according to the method of claim 25.

64. A light emitting diode, comprising:
a plurality of gallium nitride nanowires of a first conductivity type;
a plurality of indium gallium nitride/gallium nitride multi-quantum wells disposed on facets of the nanowires; and
a continuous gallium nitride layer of a second conductivity type disposed on the multi-quantum wells.

65. The light emitting diode of claim 64, comprising a substrate from which the nanowires extend, and a plurality of voids disposed between the nanowires and bounded by the substrate and the multi-quantum wells.

66. A method for fabricating a light emitting diode, the method comprising:
forming a plurality of gallium nitride nanowires of a first conductivity type;
depositing a plurality of indium gallium nitride/gallium nitride multi-quantum wells on facets of the nanowires; and
depositing a continuous gallium nitride layer of a second conductivity type on the multi-quantum wells.

67. The method of claim 66, comprising depositing gallium nitride on a growth surface of a substrate to form a first gallium nitride layer having a thickness in a growth direction; forming the nanowires by removing gallium nitride from the first gallium nitride layer such that the nanowires extend from the growth surface along the growth direction and comprise respective tip regions, and the tip regions comprise facets; and depositing additional gallium nitride to grow crystals from the facets, wherein crystals growing from neighboring facets coalesce to form the multi-quantum wells and the continuous gallium nitride layer, and a plurality of voids are dispersed throughout an interfacial region of the first gallium nitride layer between the growth surface and the multi-quantum wells.

68. The method of claim 67, comprising removing the substrate.

69. The method of claim 68, comprising adding a heat sink in the place of the removed substrate.
